(19) United States
(12) Patent Application Publication
(10) Pub. No.: US 2016/0141556 A1
(43) Pub. Date: May 19, 2016

(54) SURFACE EMITTING DEVICE AND SMART DEVICE

(71) Applicant: KONICA MINOLTA, INC., Tokyo (JP)

(72) Inventor: Natsuki YAMAMOTO, Kawasaki-shi, Kanagawa (JP)

(21) Appl. No.: 14/901,380

(22) PCT Filed: Jun. 23, 2014
(86) PCT No.: PCT/JP2014/066518

§ 371 Date: Dec. 28, 2015

(30) Foreign Application Priority Data
Jun. 27, 2013 (JP) 2013-134693

(51) Int. Cl. H01L 51/52

(52) U.S. Cl. CPC H01L 51/5281

(57) ABSTRACT

The purpose of the present invention is to provide a surface emitting device in which the light output surface appears black at times that light is not being emitted, and areas in which patterns are formed are not visible at times that light is not being emitted. This surface emitting device (10) is characterized by being provided with: an organic EL element (3) in which an organic functional layer (33) having at least a light-emitting layer is sandwiched between an anode (32) and a cathode (34) formed on a support substrate (31), and in which a predetermined area of the organic functional layer (33) has been patterned through irradiation with light; a fastening substrate (1) facing the support substrate (31), for supporting the organic EL element (3); and a circular polarizing plate (2) situated between the organic EL element (3) and the fastening substrate (1).

### TECHNICAL FIELD

The present invention relates to a surface emitting device and a smart device. Especially, the present invention relates to a surface emitting device whose light emission surface appears as black when the light is not emitted and whose patterned region cannot be visually recognized when the light is not emitted, and a smart device provided with the same.

### BACKGROUND ART

Examples of traditional planar light sources include light emitting diodes (LEDs) provided with light guide plates and organic light emitting diodes (OLEDs) (hereinafter also referred to as “organic electroluminescent element”).

The LED light sources provided with light guide plates, which have been typically used as illuminating lamps for general use, is used as the backlights of main displays (e.g., liquid crystal displays (LCDs)) for smart devices (e.g., smartphones and tablets).

LED light sources, which are used as backlights for main displays, are also used as backlights for common function key buttons provided in lower portions of smart devices.

Some common function key buttons are provided with three marks indicating “Home” (e.g., represented by a square mark) “Back” (e.g., represented by an arrow mark), and “Search” (e.g., represented by a magnifier mark).

Such common function key buttons are provided with LED light sources with light guide plates. Such a light guide plate has a dotted polarizing pattern conforming to the pattern of the mark to be displayed and has LED light sources at the edges. The LED light sources emit light on the side surfaces of the light guide plate. Light from the LED light sources enters the light guide plate from the side surfaces and then is totally reflected on the reflection surface of the polarizing pattern toward the front of the light guide plate. Consequently, light with a predetermined pattern is emitted from the front side of the light guide plate, so that the viewer sees light with such a pattern when viewing the light guide plate from the front (for example, see PTL 1).

If the portion in which common function key buttons are provided is in black in the smart device, for example, a technique of providing a polarizing material or a filter having low light transmittance at the observing side of the common function key buttons is employed. According to the technique, the external light reflection due to the internal structure of the common function key buttons is reduced and the light emission surface of the common function key buttons appears as black when the light is not emitted.

However, even if a polarizing material or a filter having low light transmittance at the observing side (on the front side of the light guide plate) is provided, the light guide plate can be slightly seen through it, because the conventional common function key buttons as described above has a light guide plate having light transmittance. Therefore, the light emission surface does not perfectly appear as black when the light is not emitted. Since the light emission surface does not perfectly appear as black, the polarizing patterns directly formed on the light guide plate can be visually recognized when the light is not emitted.

### PRIOR ART DOCUMENT

### Patent Literature

[PTL 1] Japanese Laid-Open Patent Application Publication No. 2012-194291

### SUMMARY OF INVENTION

### Problems to be Solved by the Invention

An object of the invention, which has been accomplished under such problems and circumstances, is to provide a surface emitting device whose light emission surface appears as black when the light is not emitted and whose patterned region cannot be visually recognized when the light is not emitted, and a smart device provided with the same.

### Means for Solving the Problem

The inventors have been studying the source and solution of the problems described above, and have completed a surface emitting device including an organic electroluminescent element having a pair of electrodes formed on a support substrate and at least one organic functional layer between the pair of electrodes, wherein a predetermined region of the organic functional layer is patterned by light irradiation; a fixed substrate facing the support substrate and supporting the organic electroluminescent element; and a circularly polarizing plate between the organic electroluminescent element and the fixed substrate. This provides a surface emitting device whose light emission surface appears as black when the light is not emitted and whose patterned region cannot be visually recognized when the light is not emitted, and a smart device provided with the same.

The present invention involves the following aspects:

1. A surface emitting device including; an organic electroluminescent element having a pair of electrodes formed on a support substrate and an organic functional layer comprising at least a luminous layer between the pair of electrodes, wherein a predetermined region of the organic functional layer is patterned by light irradiation; a fixed substrate facing the support substrate and supporting the organic electroluminescent element; and a circularly polarizing plate between the organic electroluminescent element and the fixed substrate.
2. The surface emitting device of item 1, wherein a layer patterned by the light irradiation is a hole transport layer or a hole injection layer in the organic functional layer.
3. A smart device provided with the surface emitting device of item 1 or 2.

### Advantageous Effects of Invention

The present invention provides a surface emitting device whose light emission surface appears as black when the light is not emitted and whose patterned region cannot be visually recognized when the light is not emitted, and a smart device provided with the same.

The appearance mechanism of the effects and action mechanism of the present invention are as follows.

The organic functional layer of the organic electroluminescent element patterned by irradiating light can emit light with a predetermined pattern without changing the outer appearance of the organic electroluminescent element. Therefore, the patterned region is not visually recognized when the light is not emitted. The circularly polarizing plate provided between the organic electroluminescent element and the fixed substrate reduces the external light reflection by the organic electroluminescent element. As a result, the light emission surface appears as black when the light is not emitted.

### BRIEF DESCRIPTION OF DRAWINGS

FIG. 1A is a diagrammatic view illustrating the surface emitting device and the smart device provided with the same according to the present invention.

FIG. 1B is a diagrammatic view illustrating the surface emitting device and the smart device provided with the same according to the present invention.

### EMBODIMENT FOR CARRYING OUT THE INVENTION

A surface emitting device according to the present invention includes an organic electroluminescent element having a pair of electrodes formed on a support substrate and at least one organic functional layer between the pair of electrodes, wherein a predetermined region of the organic functional layer is patterned by light irradiation; a fixed substrate facing the support substrate and supporting the organic electroluminescent element; and a circularly polarizing plate provided between the organic electroluminescent element and the fixed substrate. These technical features are commonly owned by the inventions according to claims 1 to 3.

In the present invention, a hole transport layer or a hole injection layer in the organic functional layer is preferably patterned by light irradiation. According to such configuration, patterning can be conducted before sealing and immediately after forming a hole transport layer or a hole injection layer in manufacturing an organic EL element by light irradiation without through a sealing material or other constituent layers of the organic EL element. Accordingly, the predetermined region of the organic EL element can be patterned accurately.

Hereinafter, the present invention, its constituents and embodiments for carrying out the present invention are detailed. Note that, in the present invention, “to” between values is used to mean that the values before and after the sign are inclusive as the lower limit and the upper limit.

### <<Configuration of Surface Emitting Device and Smart Device>>

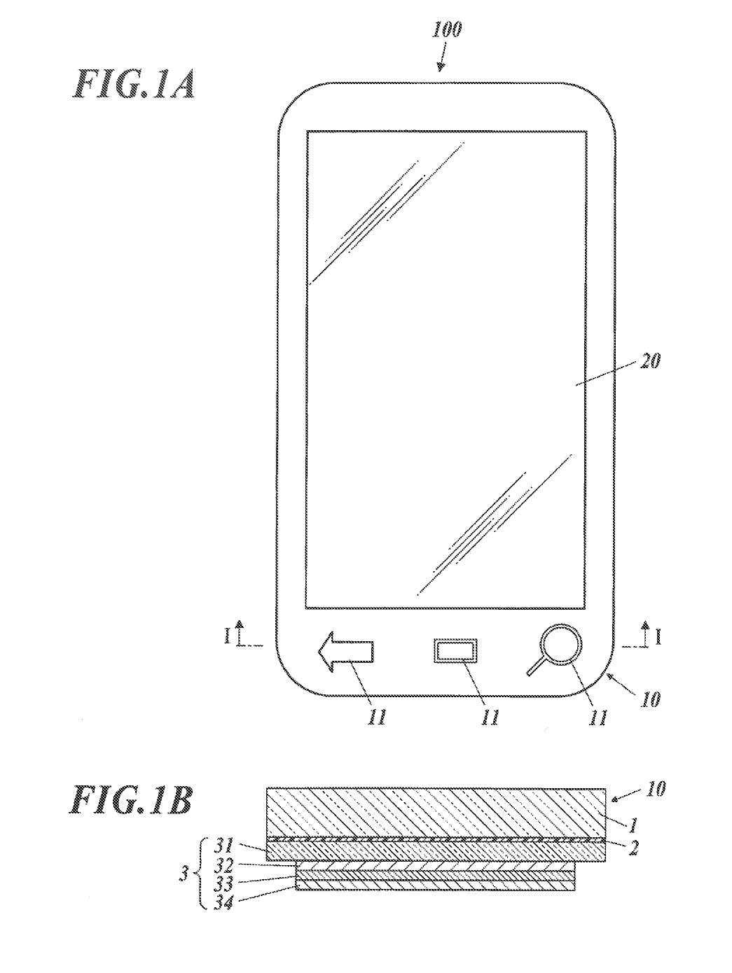

The surface emitting device and the smart device provided with the same of the present invention are illustrated in FIGS. 1A and 1B. FIG. 1A is a schematic front view illustrating the smart device 100 and FIG. 1B is a cross-sectional view along the line I-I in FIG. 1A, illustrating the schematic cross-sectional view of the surface emitting device 10 included in the smart device 100.

The smart device 100 according to the present invention is provided with a surface emitting device 10 as common function key buttons, liquid crystal display 20, and the like. A conventionally-known liquid crystal display can be used as the liquid crystal display 20.

FIG. 1A illustrates the surface emitting device 10 in a light emitting state, in which the light emission of various patterns 11 can be visually recognized from the front. When the surface emitting device 10 is in the non-light emitted state, the various patterns 11 cannot be visually recognized. FIG. 1A merely shows examples of the shapes of the patterns 11 and does not limit them. The pattern 11 may be in any shape, such as a figure, a character, a design, and the like.

Hereinafter, the term “a pattern” is used to mean a design (pattern or design of a figure), a character, or an image represented by the light emission of the organic EL element. The term “patterning” is used to mean the addition of a function of representing the pattern.

As shown in FIG. 1B, the surface emitting device 10 is provided with a fixed substrate 1, circularly polarizing plate 2, and an organic electroluminescent element (hereinafter, also referred to as an “organic EL element”) 3, and the like, laminated in this order.

The circularly polarizing plate 2 is provided facing the support substrate 31 of the organic EL element 3.

The organic EL element 3 is a one-side light emitting element which emits light from the side of the circularly polarizing plate 2. As described below, it is patterned by light irradiation in advance and emits light only from the region of patterns 11 when observed from the front side as shown in FIG. 1A. Accordingly, the front side of the surface emitting device 10 is the light emitting surface.

A touch panel etc. (not shown in the drawings) is provided between the fixed substrate 1 and the circularly polarizing plate 2.

According to the circularly polarizing plate 2 provided between the fixed substrate 1 and the organic EL element 3, the reflected light which enters from the side of the fixed substrate 1, passes through the circularly polarizing plate 2, and is reflected at the electrode etc. constituting the organic EL element 3 can be absorbed. Accordingly, the light emission surface appears as black when the light is not emitted and observed from the side of the fixed substrate 1.

Because the organic EL element 3 is patterned by light irradiation in advance as described below, the light can be emitted in a desired pattern of shape without changing the outer appearance of the organic EL element 3, and the region corresponding to the pattern is not visually recognized when the light is not emitted.

The members constituting the surface emitting device 10 is detailed below.

### <<Fixed Substrate>>

A fixed substrate 1 is a translucent plate member covering the circularly polarizing plate 2 and the organic EL element 3, and fixed facing the circularly polarizing plate 2 via an adhesive not shown in the drawings.

Specific examples of the fixed substrate 1 include glass substrates and polymer substrates. Examples of materials for the glass substrate include soda-lime glass, barium-strontium-containing glass, lead glass, aluminosilicate glass, borosilicate glass, barium borosilicate glass, and quartz. Examples of materials for the polymer substrate include polycarbonates, acrylics, poly(ethylene terephthalate), polyether sulfides, and polysulfones.

### <<Circularly Polarizing Plate>>

The circularly polarizing plate 2 absorbs the external light which enters from the fixed substrate 1 and reflects at the organic EL element 3, so as to make the light emission surface of the surface emitting device 10 appears as black when the light is not emitted. The circularly polarizing plate 2 further transmits the light emitted from the organic EL element 3. As the circularly polarizing plate 2, commercially available ones can be used.

The polarizer, which is a main component of the circularly polarizing plate, can transmit only a light component having a polarization plane in a predetermined direction. Typical known polarizers include poly(vinyl alcohol) polarizing films. This is mainly classified into poly(vinyl alcohol) films dyed with iodine and those dyed with dichroic dyes. The polarizer can be prepared by the following procedure: A poly(vinyl alcohol) aqueous solution is formed into a film. The film is monoaxially stretched, and is dyed, or vice versa. The resulting film is preferably treated with a boron compound to give durability. The polarizer has a thickness of preferably 5 to 30 μm, more preferably 8 to 15 μm.

A circularly polarizing plate is constituted by laminating the above polarizer and a λ/4 plate (λ/4 phase difference film). A polarizer functions as a circularly polarizing plate when laminated with a λ/4 plate.

A λ/4 plate has a property that shifts the phase of a light having a predetermined wavelength (normally in the wavelength of visible light range) by the in-plane retardation value Ro of approximately ¼, and can convert linearly-polarized light to elliptically- or circularly-polarized light and elliptically- or circularly-polarized light to linearly-polarized light.

The specific constitution of the λ/4 plate is not particularly limited, and conventionally-known knowledge can be referred to as necessary. The λ/4 plate is composed of a transparent resin, which has a transmittance preferably 60% or more for visible light, more preferably 80% or more, and particularly preferably 90% or more. The transparent resin composing the λ/4 plate is preferably a thermoplastic resin. The transparent resin preferably has a positive intrinsic birefringence value. The examples of the transparent resin composing the λ/4 plate include a cellulose ester resin, a polyolefinic resin, a polysulfone resin, a polycarbonate resin, a polymethyl methacrylate resin, a polyester resin, and a polyvinyl alcohol resin.

The λ/4 plate can be manufactured by forming a film of these resins by solution casting or melt casting, and by stretching (stretching operation in casting direction, in width direction, in oblique direction, and the like are combined) the film etc., in order to provide a retardation property described above. An oblique stretching machine can be preferably used for manufacturing the λ/4 plate. The λ/4 plate manufactured by using the oblique stretching machine has a slow axis in an direction of substantially 45° with respect to the longitudinal direction of the film. Thus manufactured λ/4 plate can be stuck to a polarizer by roll-to-roll process and the productivity in manufacturing the circularly polarizing plate is remarkably improved. In sticking the λ/4 plate to a polarizer, an aqueous adhesive composed mainly of a fully saponified polyvinyl alcohol etc. is preferably used.

When the external light enters into the surface emitting device 10 provided with the circularly polarizing plate constituted as above, only the linearly-polarized component of the light parallel to the direction of the polarization axis of the polarizer passes through the polarizer. Other components are absorbed by the polarizer. The linearly-polarized light passing through the polarizer is converted to a circularly-polarized light, because it passes through a λ/4 plate. When reflected at the electrode etc. in the organic EL element 3, the circularly-polarized light becomes a circularly-polarized light having an inversed rotation direction. The circularly-polarized light having an inversed rotation direction is converted to a linearly-polarized light having a direction of 90° with respect to the polarization axis of the polarizer. The resulting linearly-polarized light cannot pass through the polarizer and is absorbed. As described above, the external light entering into the surface emitting device 10 is completely absorbed by the polarizer and light reflection is reduced.

Further, a commercially available polarizing plate protective film is preferably used on the surface of the circularly polarizing plate 2. Specific examples thereof are: KC8UX2MW, KC4UX, KC5UX, KC4UY, KC8UY, KC12UR, KC4UEW, KC8UCR-3, KC8UCR-4, KC8UCR-5, KC4FR-1, KC4FR-2, KC8UE, and KC4UE (made by Konica Minolta, Inc.).

An adhesive (not shown in the drawings) used for bonding a circularly polarizing plate 2 facing the support substrate 31 constituting the organic EL element 3 is preferably a substance of optically transparent and also exhibiting appropriate elasticity and adhesiveness.

Specific examples are: an acrylic copolymer, an epoxy resin, polyurethane, a silicone polymer, polyether, a butyral resin, a polyamide resin, a polyvinyl alcohol resin and a synthetic rubber. Among them, an acrylic copolymer is preferably used since its adhesion property can be controlled most easily and it is excellent in transparency, weather-resistancy, and durability.

These adhesives can be applied between the circularly polarizing plate 2 and a support substrate 31 and can be formed into a film by curing with a method such as: a drying method, a chemical curing method, a thermo-setting method, a thermo-melting method, and a photo-curing method.

### <<Constitution of Organic EL Element>>

A shown in FIG. 1B, an organic EL element 3 is constituted of a support substrate 31, an anode 32, an organic functional layer 33, and a cathode 34 laminated in this order. The anode 32 may be connected to an external power source (not shown in the drawings) via an extracting electrode provided at the end of the anode 32.

The emitted light is extracted from the side of the support substrate 31 in the organic EL element 3.

The organic EL element 3 is patterned by light irradiation and emits light with a pattern of predetermined shapes.

The organic functional layer 33 includes at least a luminous layer. The preferable examples of layer constitution of organic functional layer 33 are shown below, but do not limit the present invention.

(i) Hole injection-transport layer/luminous layer/electron injection-transport layer
(ii) Hole injection-transport layer/luminous layer/hole blocking layer/electron injection-transport layer
(iii) Hole injection-transport layer/electron blocking layer/luminous layer/hole blocking layer/electron injection-transport layer
(iv) Hole injection layer/hole transport layer/luminous layer/electron transport layer/electron injection layer
(v) Hole injection layer/hole transport layer/luminous layer/hole blocking layer/electron transport layer/electron injection layer
(vi) Hole injection layer/hole transport layer/electron blocking layer/luminous layer/hole blocking layer/electron transport layer/electron injection layer

Individual layers constituting the organic functional layer 33 can be formed by any known thin-film forming process, for example, vacuum deposition, spin coating, casting, Langmuir Blodgett (LB) coating, ink jetting, spray coating, printing, or slot type coating.

Between the anode 32 and the cathode 34 of the organic EL element 3, a plurality of organic functional layers 33 may be laminated via intermediate electrode(s). In this case, each of the plurality of organic functional layers 33 may emit light with different pattern of shape.

The layers in the organic EL element 3 according to the present invention will now be described.

### <Luminous Layer>

A luminous layer preferably includes a host compound and a light emitting dopant.

The light emitting dopant may be contained in the luminous layer at a uniform concentration or may have a concentration distribution across the thickness of the luminous layer.

Each luminous layer included in the light-emitting units may have any thickness, preferably within the range of 5 to 200 nm, more preferably within the range of 10 to 100 nm, from the viewpoints of uniformity of the film to be formed, avoiding application of an excessive high voltage at the time of light emission, and an increase in stability of the color of emitted light with respect to a driving current.

Phosphorescent host compounds and phosphorescent dopants contained in the luminous layer will be now described.

### (1) Phosphorescent Host Compound

A phosphorescent host compound employed in the present invention may have any structure, and typical examples thereof include compounds having a basic skeleton such as carbazole derivatives, triarylamine derivatives, aromatic borane derivatives, nitrogen-containing heterocyclic compounds, thiophene derivatives, furan derivatives, or oligoarylene compounds, and carboline derivatives or diazacarbazole (i.e., a ring in which at least one of the carbon atoms in the carboline ring of the carboline derivatives is replaced with a nitrogen atom) derivatives.

The phosphorescent compounds may be used alone or in combination.

The phosphorescent host compound used for the phosphorescent layer of the present invention is preferably represented by General Formula (a):

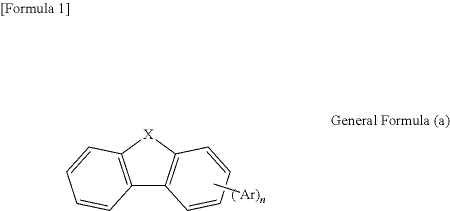

where “X” represents NR′, O, S, CR′R″ or SiR′R″, and R′ and R″ each independently represents a hydrogen atom or a substituent group. “Ar” represents an aromatic ring, and n represents an integer of 0 to 8.

Examples of the substituent group represented by each of R′ and R″ in “X” of General Formula (a) include: alkyl groups, such as methyl, ethyl, propyl, isopropyl, tert-butyl, pentyl, hexyl, octyl, dodecyl, tridecyl, tetradecyl, and pentadecyl groups; cycloalkyl groups such as cyclopentyl and cyclohexyl groups; alkenyl groups such as vinyl, allyl, 1-propenyl, 2-butenyl, 1,3-butadienyl, 2-pentenyl, and isopropenyl groups; alkynyl groups, such as ethynyl and propargyl groups; aromatic hydrocarbon ring groups (also referred to as aromatic carbocyclic groups or aryl groups), such as phenyl, p-chlorophenyl, mesityl, tolyl, xylyl, naphthyl, anthryl, azulenyl, acenaphthenyl, fluorenyl, phenanthryl, indenyl, pyrenyl, and biphenylyl groups); heterocyclic aromatic ring groups, such as furyl, thienyl, pyridyl, pyridazinyl, pyrimidinyl, pyrazinyl, triazinyl, imidazolyl, pyrazolyl, thiazolyl, quinazolinyl, carbazolyl, carbolinyl, diazacarbazolyl (a group formed by substitution of any one of the carbon atoms forming the carboline ring of the carbolinyl group), and phthalazinyl groups; heterocyclic ring groups, such as pyrrolidyl, imidazolidyl, morpholyl, and oxazolidyl groups; alkoxy groups, such as methoxy, ethoxy, propyloxy, pentyloxy, hexyloxy, octyloxy, and dodecyloxy groups; cycloalkoxy groups, such as cyclopentyloxy and cyclohexyloxy groups; aryloxy groups, such as phenoxy and naphthyloxy groups; alkylthio groups, such as methylthio, ethylthio, propylthio, pentylthio, hexylthio, octylthio, and dodecylthio groups; cycloalkylthio groups, such as cyclopentylthio and cyclohexylthio groups; arylthio groups such as phenylthio and naphthylthio groups; alkoxycarbonyl groups, such as methyloxycarbonyl, ethyloxycarbonyl, butyloxycarbonyl, octyloxycarbonyl, and dodecyloxycarbonyl groups; aryloxycarbonyl groups, such as phenyloxycarbonyl, and naphthyloxycarbonyl groups; sulfamoyl groups, such as aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, and 2-pyridylaminosulfonyl groups; acyl groups, such as acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, and pyridylcarbonyl groups; acyloxy groups, such as acetyloxy, ethylcarbonyloxy, butylcarbonyloxy, octylcarbonyloxy, dodecylcarbonyloxy, and phenylcarbonyloxy groups; amide groups, such as methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, and naphthylcarbonylamino groups; carbamoyl groups, such as aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, and 2-pyridylaminocarbonyl groups; ureido groups such as methylureido, ethylureido, pentylureido, cyclohexylureido, octylureido, dodecylureido, phenylureido, naphthylureido, and 2-pyridylaminoureido groups; sulfinyl groups such as methylsulfinyl, ethylsulfinyl, butylsulfinyl, cyclohexylsulfinyl, 2-ethylhexylsulfinyl, dodecylsulfinyl, phenylsulfinyl, naphthylsulfinyl, and 2-pyridylsulfinyl groups; alkylsulfonyl groups, such as methylsulfonyl, ethylsulfonyl, butylsulfonyl, cyclohexylsulfonyl, 2-ethylhexylsulfonyl, and dodecylsulfonyl groups; arylsulfonyl groups; heteroarylsulfonyl groups, such as phenylsulfonyl, naphthylsulfonyl, and 2-pyridylsulfonyl groups; amino groups, such as amino, ethylamino, dimethylamino, butylamino, cyclopentylamino, 2-ethylhexylamino, dodecylamino, anilino, naphthylamino, and 2-pyridylamino groups; halogen atoms, such as fluorine, chlorine, and bromine atoms; fluorohydrocarbon groups, such as fluoromethyl, trifluoromethyl, pentafluoroethyl, and pentafluorophenyl groups; cyano groups; nitro groups; hydroxy groups; mercapto groups; silyl groups, such as trimethylsilyl, triisopropylsilyl, triphenylsilyl, and phenyldiethylsilyl groups; and phosphono groups.

These substituent groups may further be substituted by the above substituent groups. These substituent groups may also be bonded to each other to form a ring.

In General Formula (a), “X” is preferably NR′ or O, and particularly preferred examples of R′ include aromatic hydrocarbon ring groups and heterocyclic aromatic ring groups.

Examples of the aromatic ring represented by “Ar” in General Formula (a) include an aromatic hydrocarbon ring and a heterocyclic aromatic ring.

The aromatic ring represented by “Ar” may be monocyclic, fused, or unsubstituted, or may have the substituent groups represented by R′ or R″ described above.

Examples of the aromatic hydrocarbon ring represented by “Ar” in General Formula (a) include a benzene, biphenyl, naphthalene, azulene, anthracene, phenanthrene, pyrene, chrysene, naphthacene, triphenylene, o-terphenyl, m-terphenyl, p-terphenyl, acenaphthene, coronene, fluorene, fluoranthrene, naphthacene, pentacene, perylene, pentaphene, picene, pyrene, pyranthrene, and anthraanthrene rings.

Examples of the heterocyclic aromatic ring represented by “Ar” in General Formula (a) include furan, dibenzofuran, thiophene, oxazole, pyrrole, pyridine, pyridazine, pyrimidine, pyrazine, triazine, benzimidazole, oxadiazole, triazole, imidazole, pyrazole, thiazole, indole, indazole, benzimidazole, benzothiazole, benzoxazole, quinoxaline, quinazoline, cinnoline, quinoline, isoquinoline, phthalazine, naphthyridine, carbazole, carboline, and diazacarbazole (i.e., a ring in which one of the carbon atoms in the carboline ring is further replaced with a nitrogen atom) rings.

Among the rings described above, the usable aromatic ring represented by “Ar” in General Formula (a) is preferably a carbazole, carboline, dibenzofuran, and benzene rings. Among them, carbazole, carboline, and benzene rings are particularly preferred. A benzene ring having a substituent group is particularly preferred and a benzene ring having a carbazolyl group is most preferred.

The aromatic ring represented by “Ar” in General Formula (a) is preferably a fused ring composed of three or more rings described below. Specific examples of the aromatic hydrocarbon fused ring composed of three or more rings include naphthacene, anthracene, tetracene, pentacene, hexacene, phenanthrene, pyrene, benzopyrene, benzoazulene, chrysene, benzochrysene, acenaphthene, acenaphthylene, triphenylene, coronene, benzocoronene, hexabenzocoronene, fluorene, benzofluorene, fluoranthene, perylene, naphthoperylene, pentabenzoperylene, benzoperylene, pentaphene, picene, pyranthrene, coronene, naphthocoronene, ovalene, and anthraanthrene rings.

Specific examples of the heterocyclic aromatic fused ring composed of three or more rings include an acridine, benzoquinoline, carbazole, carboline, phenazine, phenanthridine, phenanthroline, carboline, cyclazine, quindoline, thebenidine, quinindoline, triphenodithiazine, triphenodioxazine, phenanthrazine, anthrazine, perimidine, diazacarbazole (i.e., a ring in which any one of the carbon atoms in the carboline ring is replaced with a nitrogen atom), phenanthroline, dibenzofuran, dibenzothiophene, naphthofuran, naphthothiophene, benzodifuran, benzodithiophene, naphthodifuran, naphthodithiophene, anthrafuran, anthradifuran, anthrathiophene, anthradithiophene, thianthrene, phenoxathiin, and thiophanthrene (naphthothiophene) rings.

In General Formula (a), n represents an integer of 0 to 8, preferably 0 to 2. In particular, if “X” is O or S, n is preferably 1 or 2.

Non-limiting specific examples of the phosphorescent host compounds represented by General Formula (a) will be shown below.

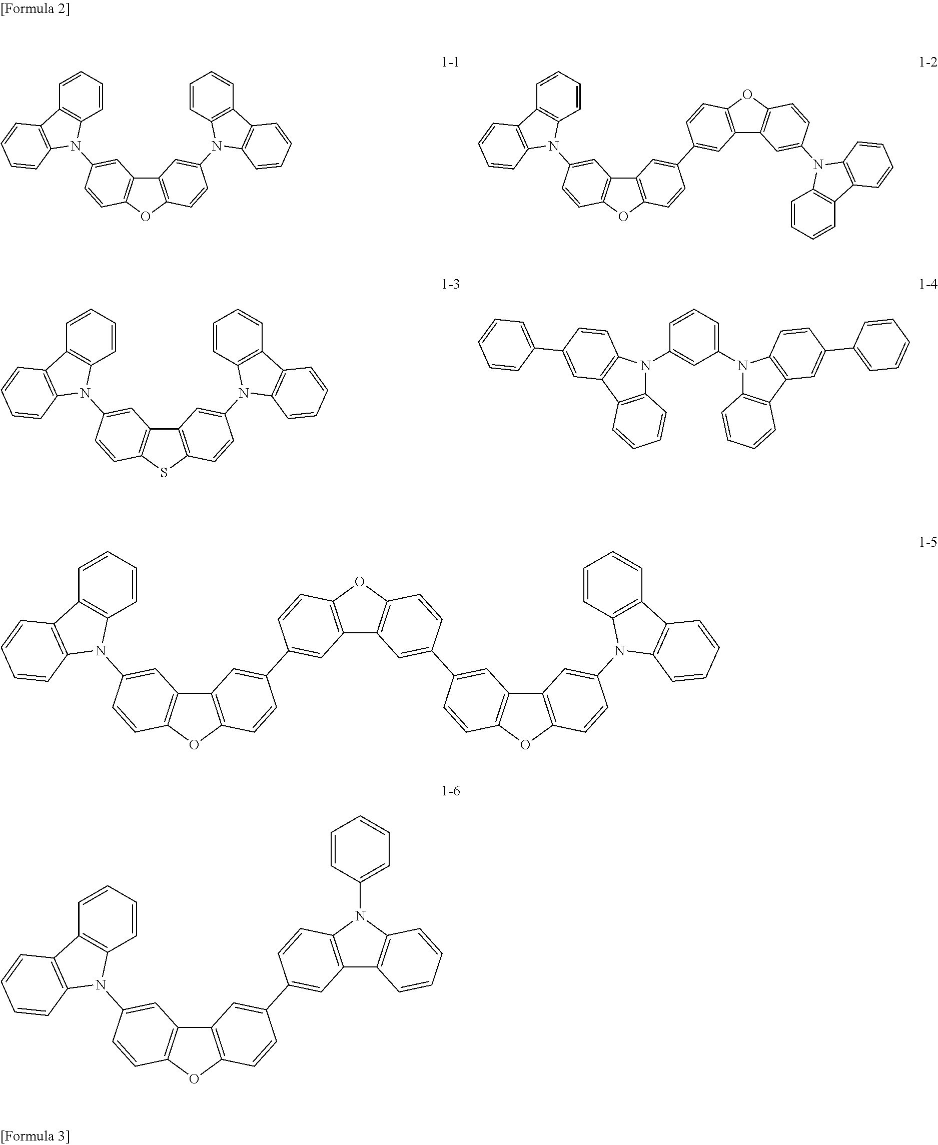

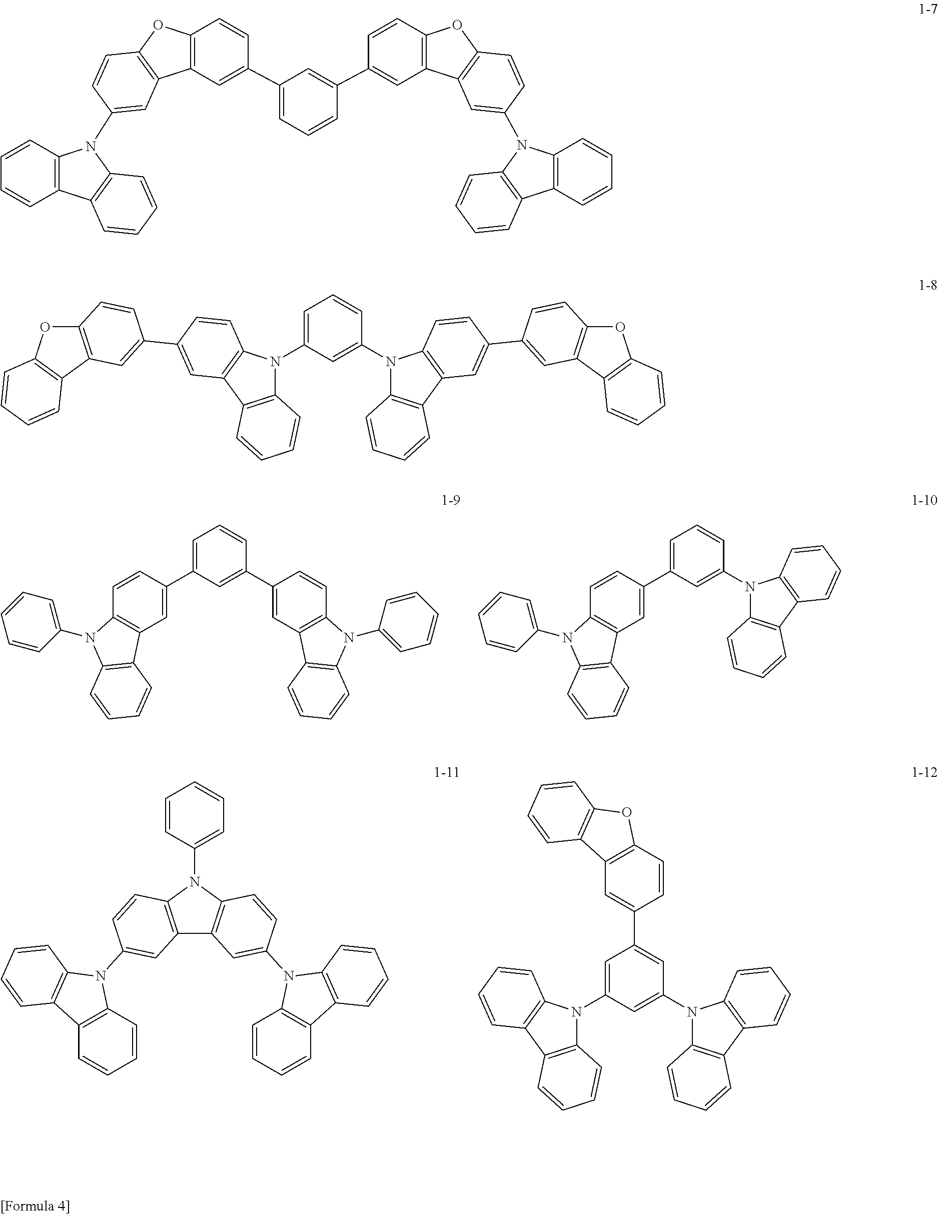

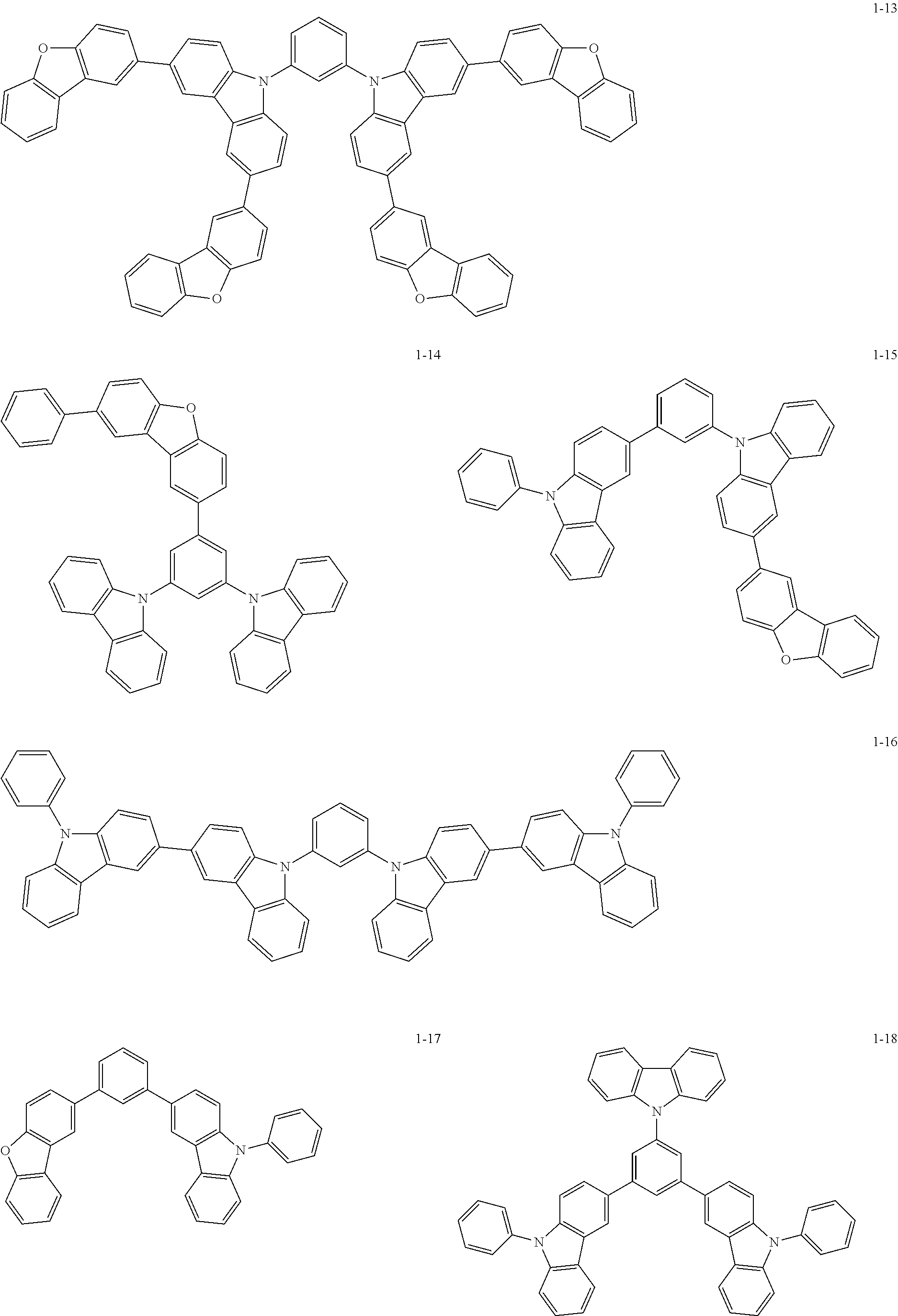

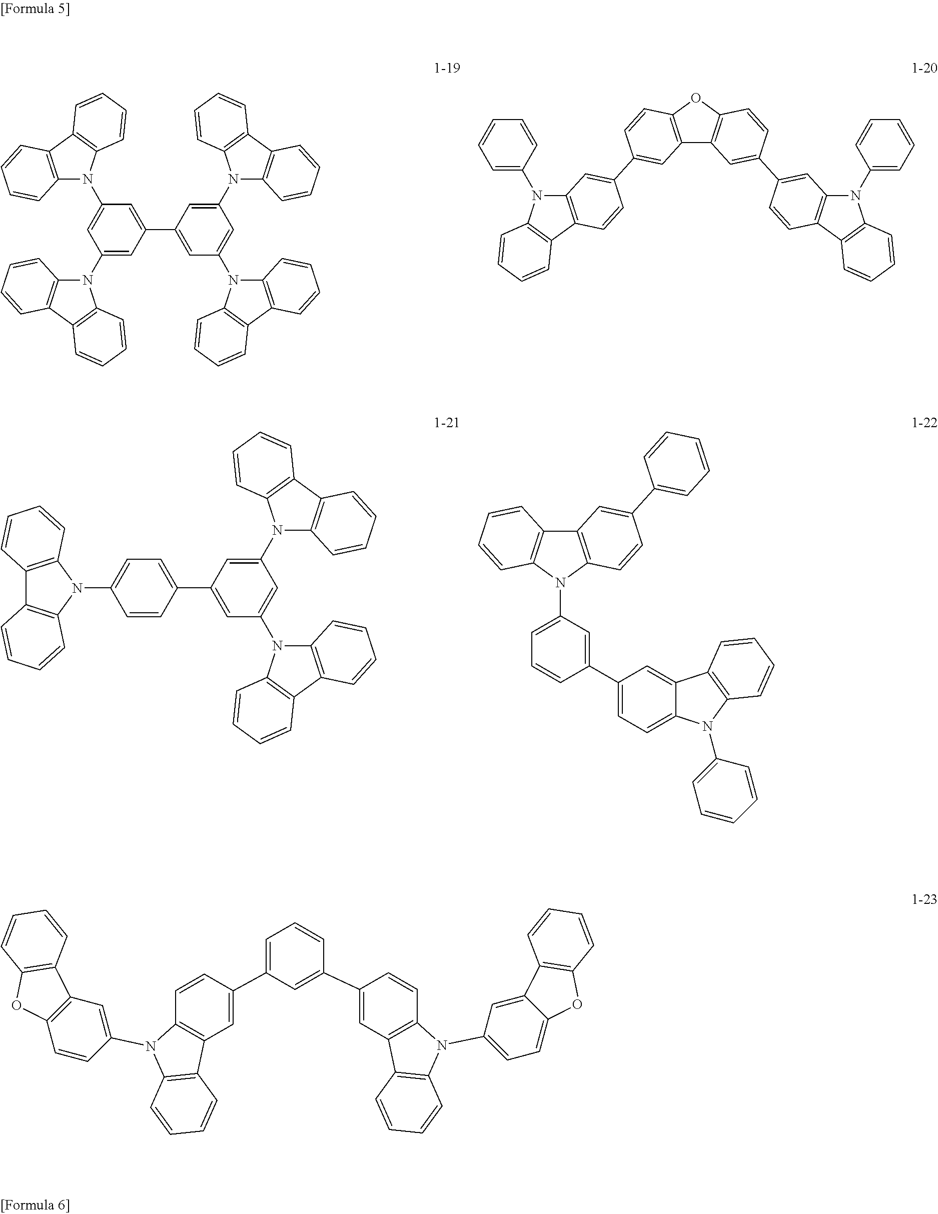

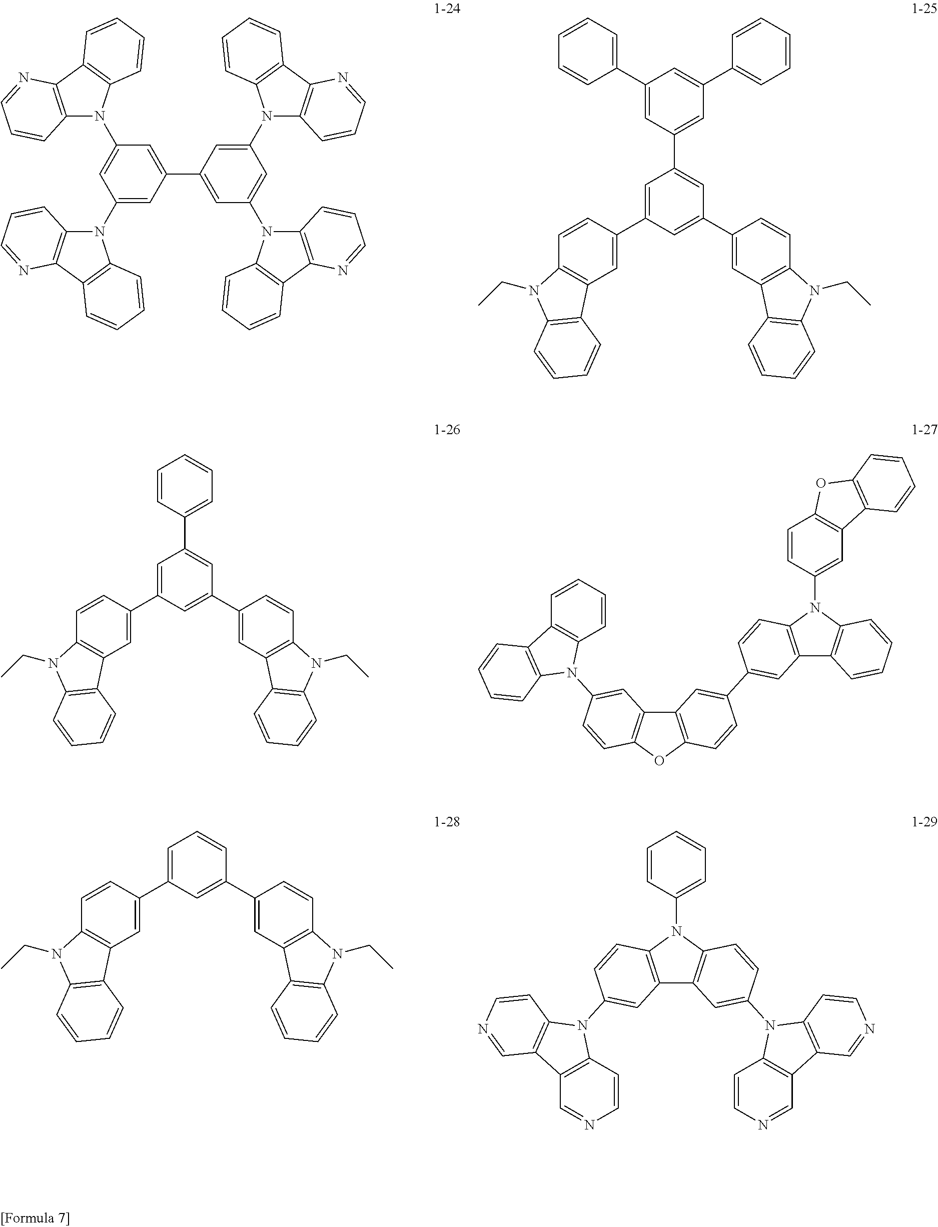

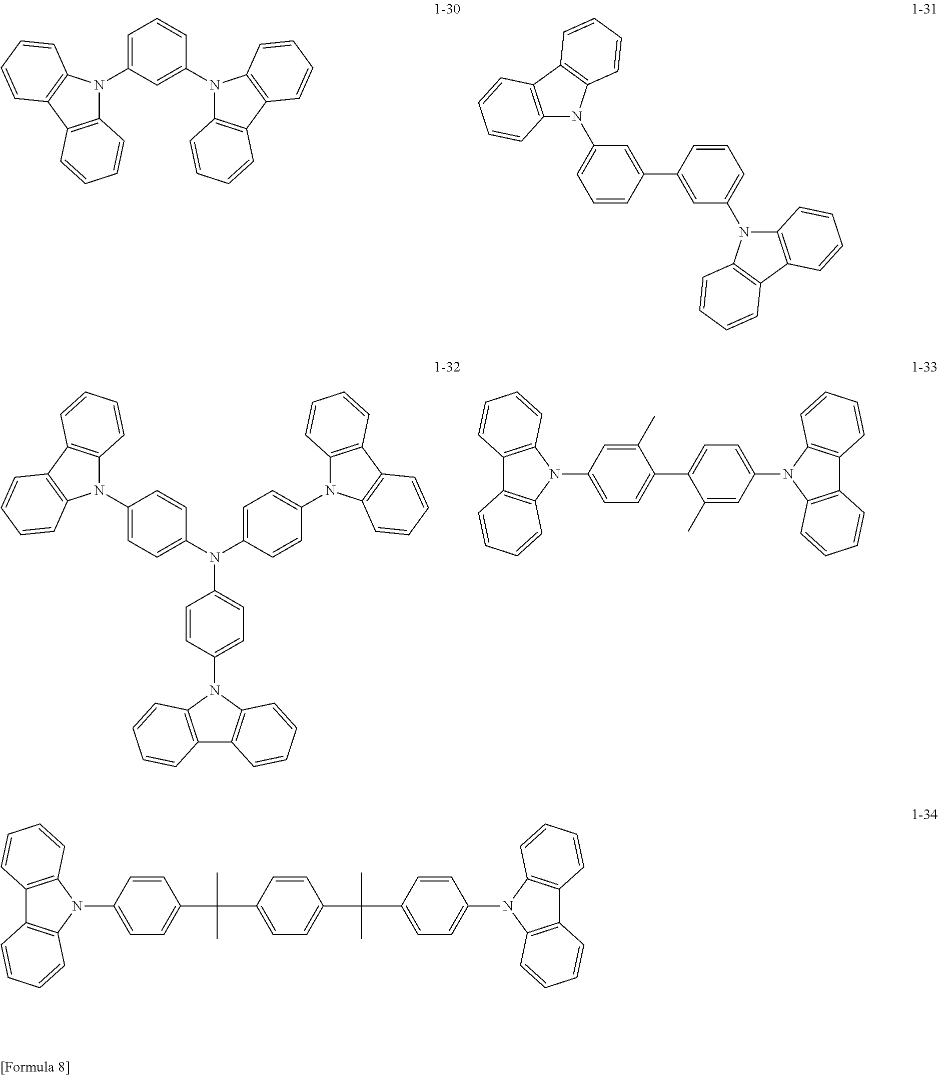

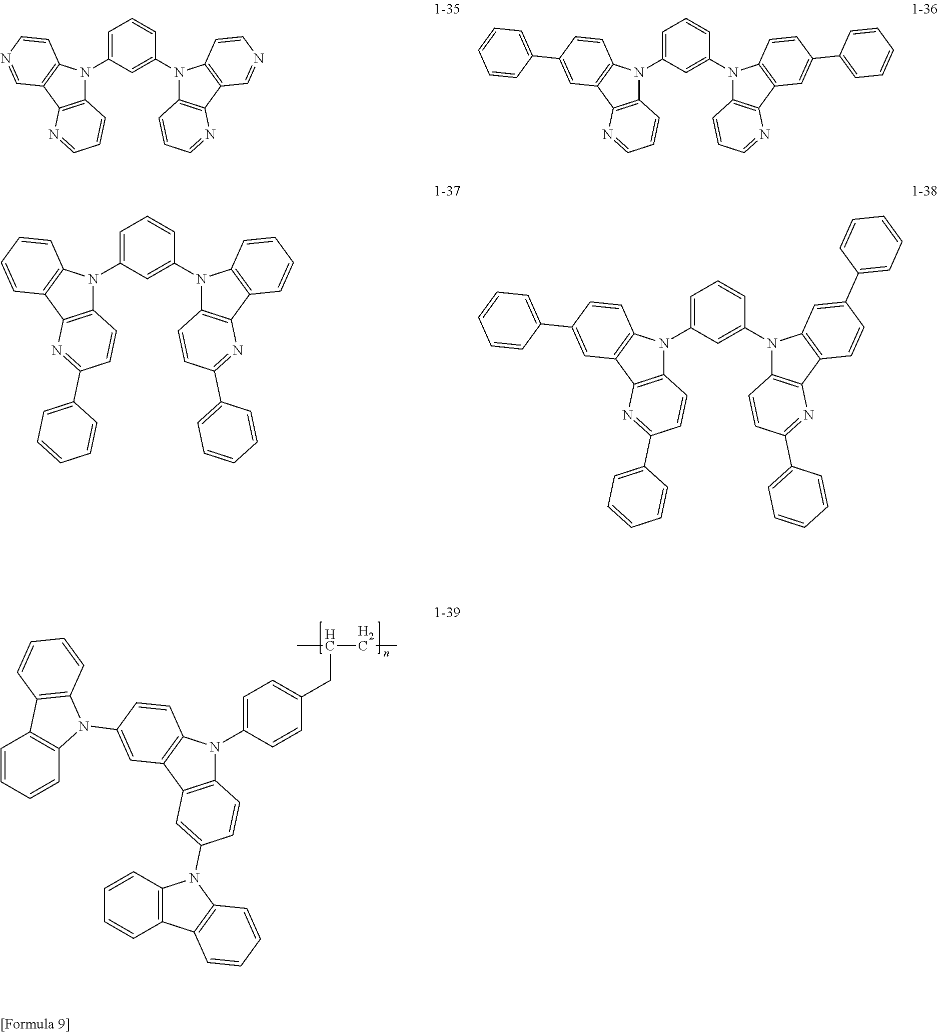

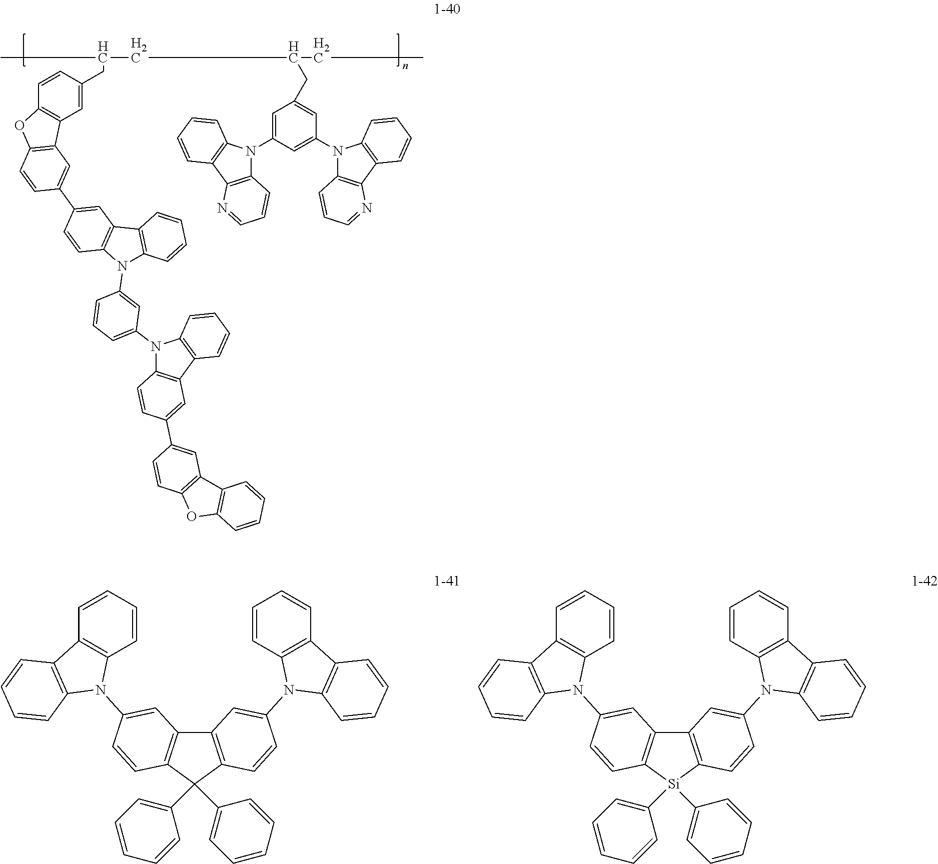

The phosphorescent host compound used in the present invention may be any compound having a low molecular weight, a polymer having repeating units, or a low-molecular-weight compound having a polymerizable group, such as a vinyl group or an epoxy group (vapor deposition polymerizable luminous host).

The phosphorescent host compound preferably has hole and electron transportability, can prevent the shift of emission toward a longer wavelength, and has a high glass transition temperature (Tg). In the present invention, compounds having a glass transition temperature of 90° C. or higher are preferred, and compounds having a glass transition temperature of 130° C. or higher are preferred more, because such compounds can provide excellent properties.

The glass transition temperature (Tg) herein is determined by differential scanning calorimetry (DSC) in accordance with JIS K 7121.

In the present invention, conventionally-known host compounds can be used.

Specific examples of preferred conventionally-known host compounds include compounds described in the following patent literatures: Japanese Laid-Open Patent Application Publication Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084, and 2002-308837.

When the organic EL element according to the present invention includes a plurality of luminous layers, the phosphorescent host compound in each luminous layer may be different from each other. However, the same phosphorescent host compound is preferably used in terms of production efficiency and process control.

The phosphorescent host compound preferably has a minimum triplet excitation energy (T₁) of above 2.7 eV for the high luminous efficiency of the resulting device.

The minimum triplet excitation energy in the present invention is determined by measuring a phosphorescent spectrum of a host compound dissolved in a solvent at a liquid nitrogen temperature. A peak energy of the phosphorescent emission band corresponding to the transition between the lowest vibrational levels is referred to as the minimum triplet excitation energy.

### (2) Phosphorescent Dopant

A conventionally-known phosphorescent dopant can be used in the present invention. For example, a complex compound including a metal in the groups 8 to 10 in the periodic table can be preferably selected, for example, an iridium compound, an osmium compound, a platinum compound (a platinum-complex compound), or a rare earth complex. The most preferable is an iridium compound.

In production of an organic EL element emitting white light, a luminescent material required for emission of light in at least the green, yellow, and red regions is preferably a phosphorescent material.

### (Partial Structures Represented by General Formulae (A) to (C))

If a blue phosphorescent dopant is used in the present invention, the blue phosphorescent dopant can be appropriately selected from known materials applicable for a luminous layer of an organic EL element, but preferably has at least one of the partial structures represented by following General Formulae (A) to (C).

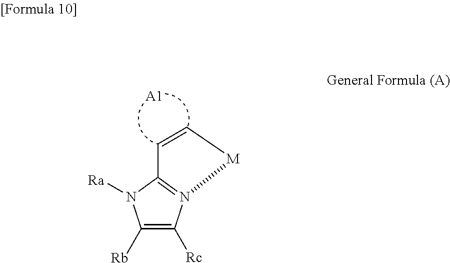

In General Formula (A), “Ra” represents a hydrogen atom, an aliphatic group, an aromatic group, or a heterocyclic group, “Rb” and “Rc” each independently represent a hydrogen atom or a substituent group, “A1” represents a residue necessary for forming an aromatic ring or heterocyclic aromatic ring, and “M” represents Ir or Pt.

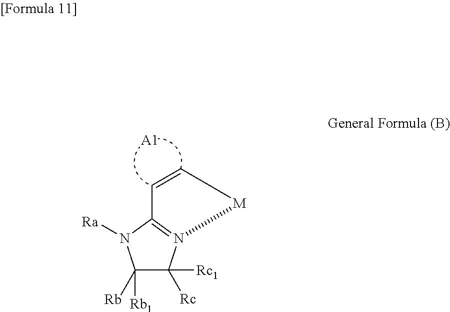

In General Formula (B), “Ra” represents a hydrogen atom, an aliphatic group, an aromatic group, or a heterocyclic group, “Rb”, “Rc”, “Rb₁”, and “Rc₁” each independently represent a hydrogen atom or a substituent group, “A1” represents a residue necessary for forming an aromatic ring or heterocyclic aromatic ring, and “M” represents Ir or Pt.

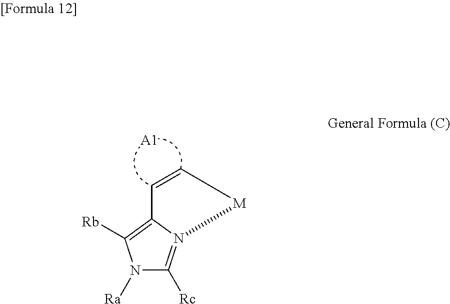

In General Formula (C), “Ra” represents a hydrogen atom, an aliphatic group, an aromatic group, or a heterocyclic group, “Rb” and “Rc” each independently represent a hydrogen atom or a substituent group, “A1” represents a residue necessary for forming an aromatic ring or heterocyclic aromatic ring, and “M” represents Ir or Pt.

Examples of the aliphatic group represented by “Ra” in General Formulae (A) to (C) include alkyl groups, such as methyl, ethyl, propyl, butyl, pentyl, isopentyl, 2-ethylhexyl, octyl, undecyl, dodecyl, and tetradecyl groups, and cycloalkyl groups, such as cyclopentyl and cyclohexyl groups. Examples of the aromatic group represented by “Ra” in General Formulae (A) to (C) include phenyl, tolyl, azulenyl, anthranyl, phenanthryl, pyrenyl, chrysenyl, naphthacenyl, o-terphenyl, m-terphenyl, p-terphenyl, acenaphthenyl, coronenyl, fluorenyl, and perylenyl groups. Examples of the heterocyclic group represented by “Ra” in General Formulae (A) to (C) include pyrrolyl, indolyl, furyl, thienyl, imidazolyl, pyrazolyl, indolizinyl, quinolinyl, carbazolyl, indolinyl, thiazolyl, pyridyl, pyridazinyl, thiadiazinyl, oxadiazolyl, benzoquinolinyl, thiadiazolyl, pyrrolothiazolyl, pyrrolopyridazinyl, tetrazolyl, oxazolyl, and chromanyl groups.

Each of these groups may have a substituent group represented by R′ or R″ in General Formula (a).

Examples of the substituent groups represented by “Rb,” “Rc,” “Rb₁” and “Rc₁” in General Formulae (A) to (C) include: alkyl groups, such as methyl, ethyl, propyl, isopropyl, tert-butyl, pentyl, hexyl, octyl, dodecyl, tridecyl, tetradecyl, and pentadecyl groups; cycloalkyl groups, such as cyclopentyl and cyclohexyl groups; alkenyl groups, such as vinyl and allyl groups; alkynyl groups, such as ethynyl and propargyl groups; aryl groups, such as phenyl and naphthyl groups; heterocyclic aromatic ring groups, such as furyl, thienyl, pyridyl, pyridazinyl, pyrimidinyl, pyradinyl, triazinyl, imidazolyl, pyrazolyl, thiazolyl, quinazolinyl, and phthalazinyl groups; heterocyclic groups, such as pyrrolidyl, imidazolidyl, morpholyl, and oxazolidyl groups; alkoxy groups, such as methoxy, ethoxy, propyloxy, pentyloxy, hexyloxy, octyloxy, and dodecyloxy groups; cycloalkoxy groups, such as cyclopentyloxy and cyclohexyloxy groups; aryloxy groups, such as phenoxy and naphthyloxy groups; alkylthio groups, such as methylthio, ethylthio, propylthio, pentylthio, hexylthio, octylthio, and dodecylthio groups; cycloalkylthio groups, such as cyclopentylthio and cyclohexylthio groups; arylthio groups, such as phenylthio and naphthylthio groups; alkoxycarbonyl groups, such as methyloxycarbonyl, ethyloxycarbonyl, butyloxycarbonyl, octyloxycarbonyl, and dodecyloxycarbonyl groups; aryloxycarbonyl groups, such as phenyloxycarbonyl and naphthyloxycarbonyl groups; sulfamoyl groups, such as aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, and 2-pyridylaminosulfonyl groups; acyl groups, such as acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, and pyridylcarbonyl groups; acyloxy groups, such as acetyloxy, ethylcarbonyloxy, butylcarbonyloxy, octylcarbonyloxy, dodecylcarbonyloxy, and phenylcarbonyloxy groups; amido groups, such as methylcarbonylamino, ethylcarbonylamino, dimethylcarbonylamino, propylcarbonylamino, pentylcarbonylamino, cyclohexylcarbonylamino, 2-ethylhexylcarbonylamino, octylcarbonylamino, dodecylcarbonylamino, phenylcarbonylamino, and naphthylcarbonylamino groups; carbamoyl groups, such as aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, and 2-pyridylaminocarbonyl groups; ureido groups, such as methylureido, ethylureido, pentylureido, cyclohexylureido, octylureido, dodecylureido, phenylureido, naphthylureido, and a 2-pyridylaminoureido groups; sulfinyl groups, such as methylsulfinyl, ethylsulfinyl, butylsulfinyl, cyclohexylsulfinyl, 2-ethylhexylsulfinyl, dodecylsulfinyl, phenylsulfinyl, naphthylsulfinyl, and 2-pyridylsulfinyl groups; alkylsulfonyl groups, such as methylsulfonyl, ethylsulfonyl, butylsulfonyl, cyclohexylsulfonyl, 2-ethylhexylsulfonyl, and dodecylsulfonyl groups; arylsulfonyl groups, such as phenylsulfonyl, naphthylsulfonyl, and 2-pyridylsulfonyl groups; amino groups, such as amino, ethylamino, dimethylamino, butylamino, cyclopentylamino, 2-ethylhexylamino, dodecylamino, anilino, naphthylamino, and 2-pyridylamino groups; halogen atoms, such as fluorine, chlorine, and bromine atoms; fluorohydrocarbon groups, such as fluoromethyl, trifluoromethyl, pentafluoroethyl, and pentafluorophenyl groups; cyano groups; nitro groups; hydroxy groups; mercapto groups; and silyl groups, such as trimethylsilyl, triisopropylsilyl, triphenylsilyl, and phenyldiethylsilyl groups.

These substituent groups may further be substituted by the above substituent groups.

Examples of the aromatic ring represented by “A1” in General Formulae (A) to (C) include a benzene, biphenyl, naphthalene, azulene, anthracene, phenanthrene, pyrene, chrysene, naphthacene, triphenylene, o-terphenyl, m-terphenyl, p-terphenyl, acenaphthene, coronene, fluorene, fluoranthrene, naphthacene, pentacene, perylene, pentaphene, picene, pyrene, pyranthrene, and anthraanthrene rings. Examples of the heterocyclic aromatic ring represented by “A1” in General Formulae (A) to (C) include a furan, thiophene, pyridine, pyridazine, pyrimidine, pyrazine, triazine, benzimidazole, oxadiazole, triazole, imidazole, pyrazole, thiazole, indole, benzimidazole, benzothiazole, benzoxazole, quinoxaline, quinazoline, phthalazine, carbazole, carboline, and diazacarbazole (i.e., a ring in which one of the carbon atoms in the carboline ring is further replaced with a nitrogen atom) rings.

In General Formulae (A) to (C), “M” represents Ir or Pt. In particular, M is preferably Ir.

The structures represented by General Formulae (A) to (C) are partial structures, and each requires a ligand corresponding to the valence of the central metal for forming a complete structure to serve as a light emitting dopant. Specific examples of the ligand include halogens, such as fluorine, chlorine, bromine, and iodine atoms; aryl groups, such as phenyl, p-chlorophenyl, mesityl, tolyl, xylyl, biphenyl, naphthyl, anthryl, and phenanthryl groups; alkyl groups, such as methyl, ethyl, isopropyl, hydroxyethyl, methoxymethyl, trifluoromethyl, and t-butyl groups; alkyloxy groups; aryloxy groups; alkylthio groups; arylthio groups; heterocyclic aromatic ring groups, such as furyl, thienyl, pyridyl, pyridazinyl, pyrimidinyl, pyradinyl, triazinyl, imidazolyl, pyrazolyl, thiazolyl, quinazolinyl, carbazolyl, carbolinyl, and phthalazinyl groups; and the partial structures of General Formulae (A) to (C) with the metal removed.

The phosphorescent dopant of the present invention is preferably a tris compound completed by three partial structures of General Formulae (A) to (C).

Non-limiting examples of the blue phosphorescent dopant having partial structures of General Formulae (A) to (C) will be listed below.

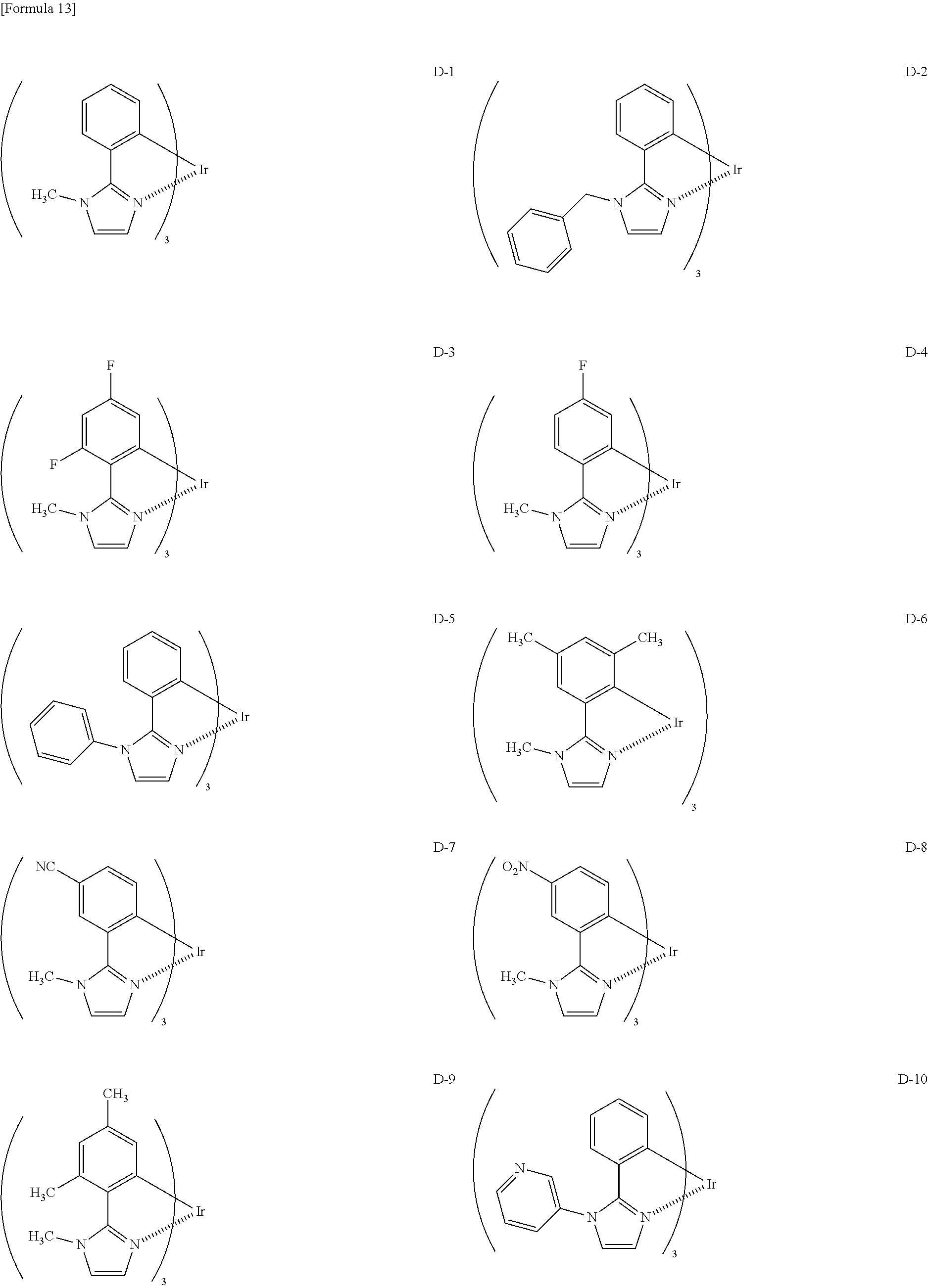

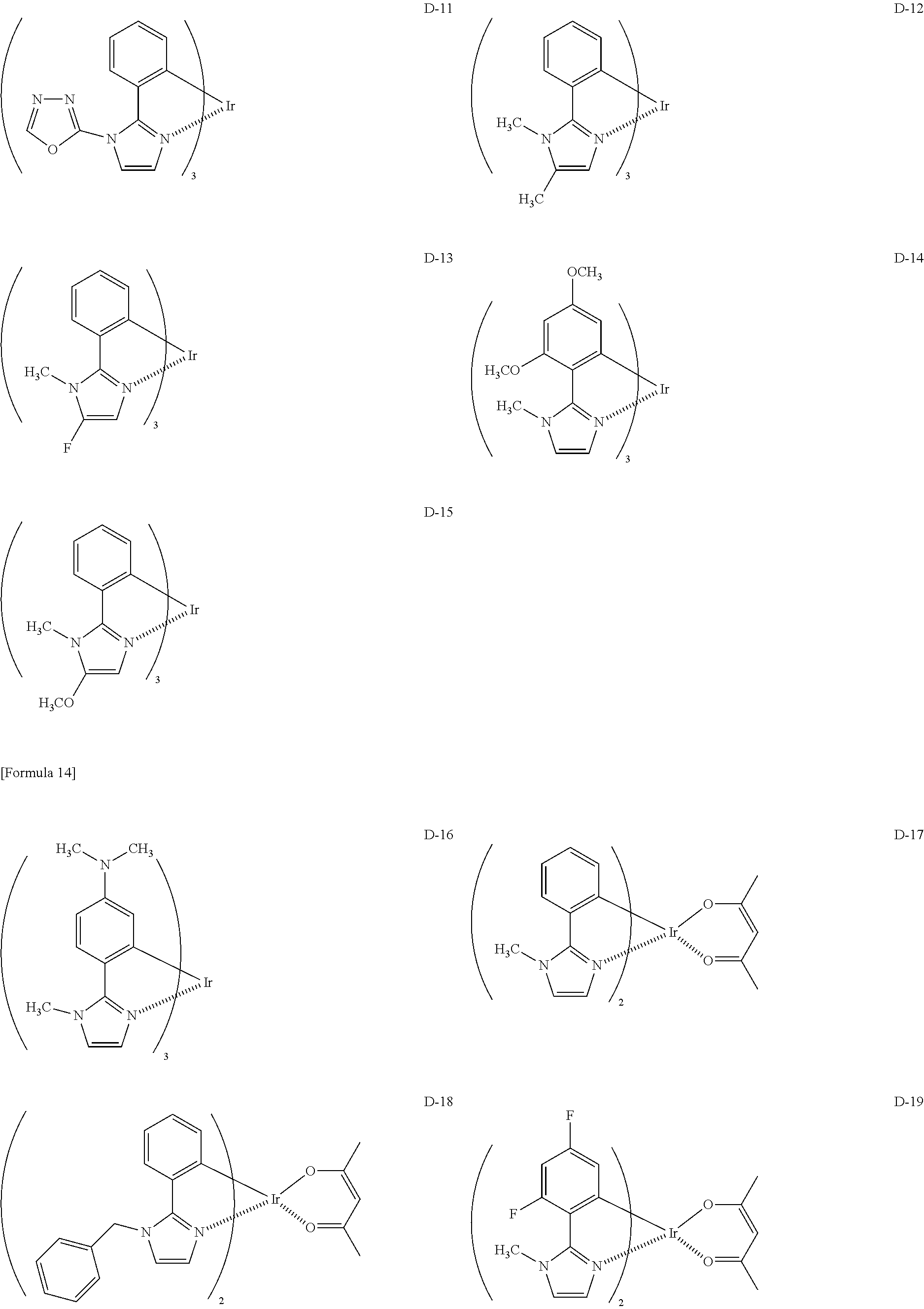

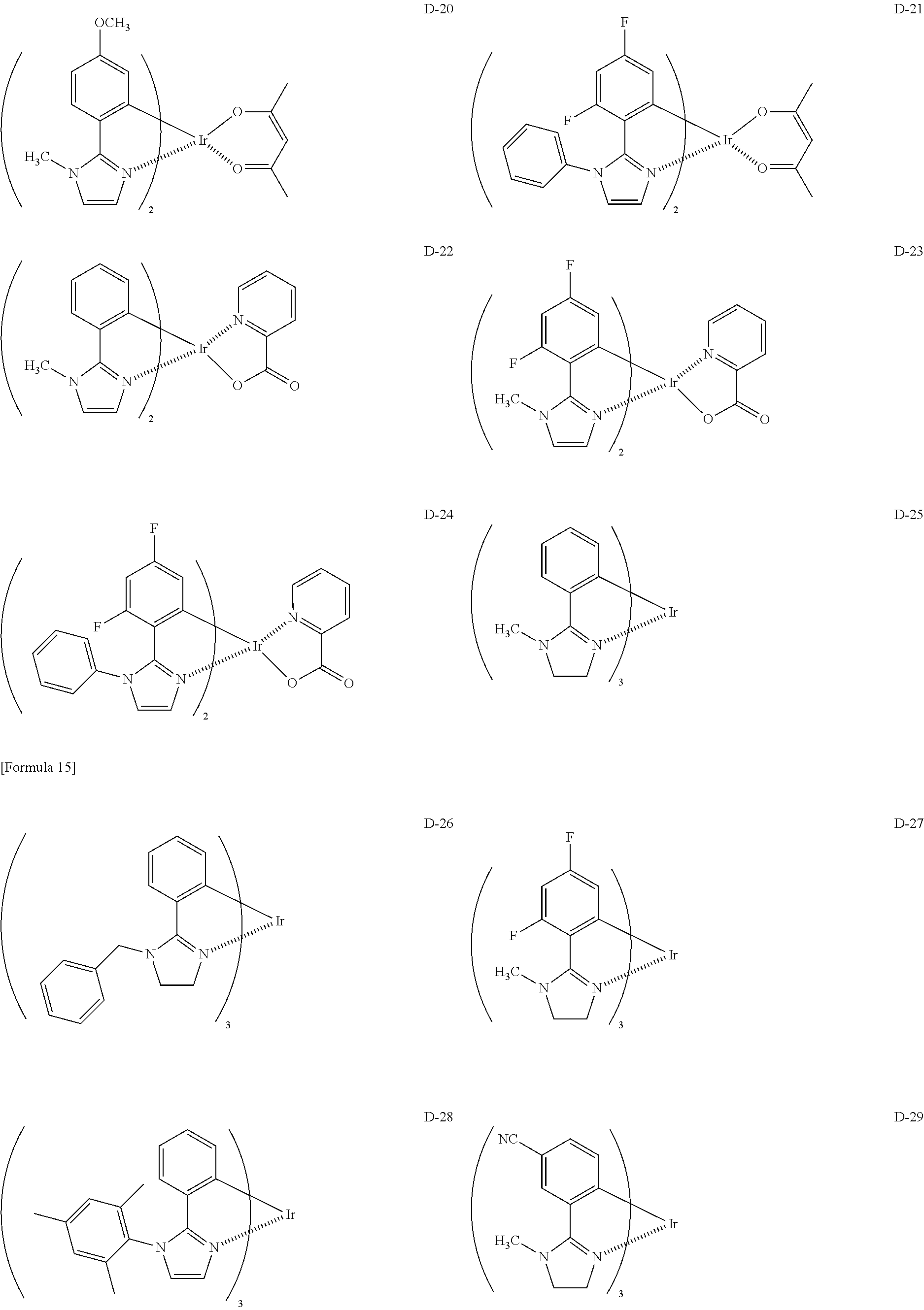

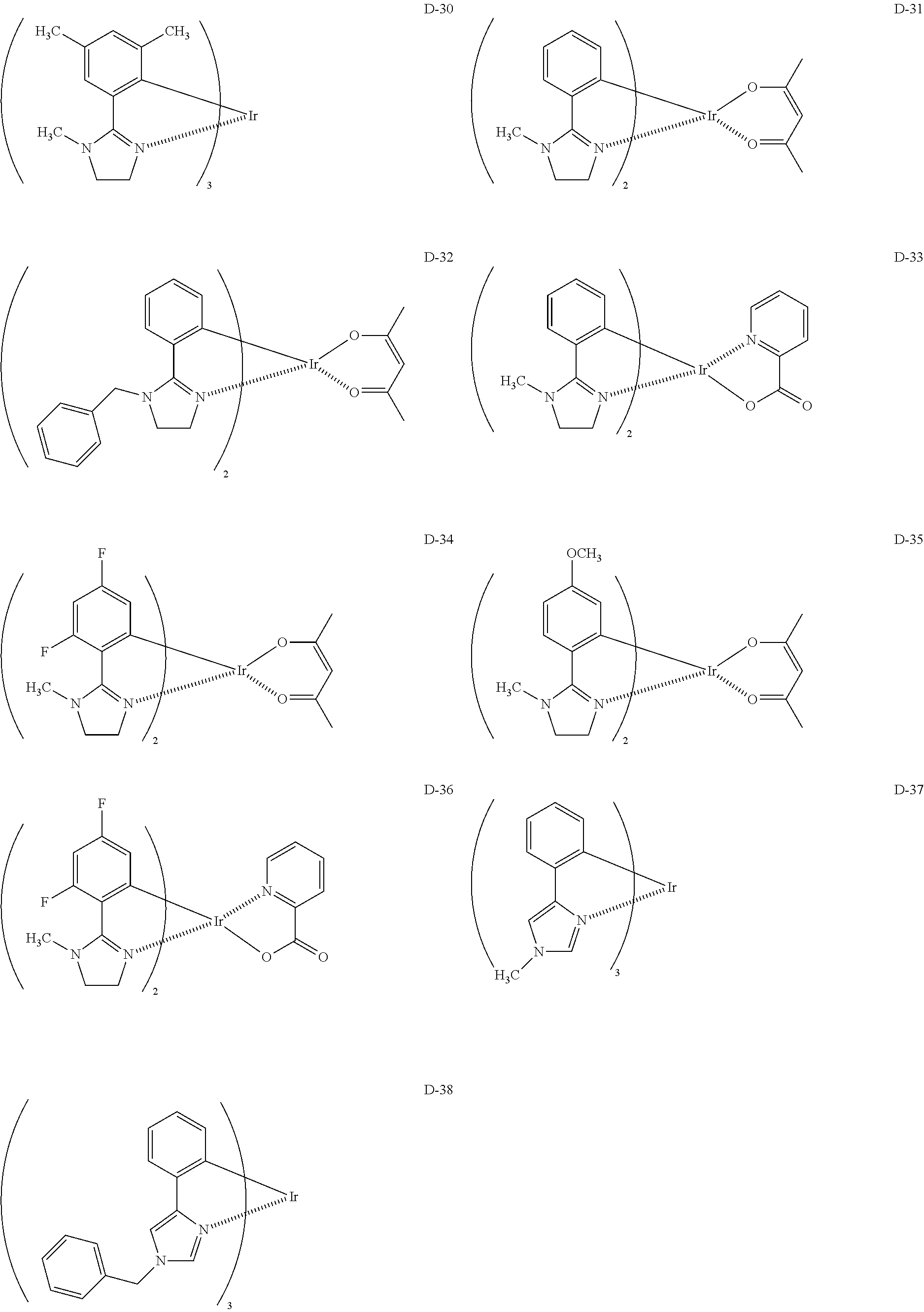

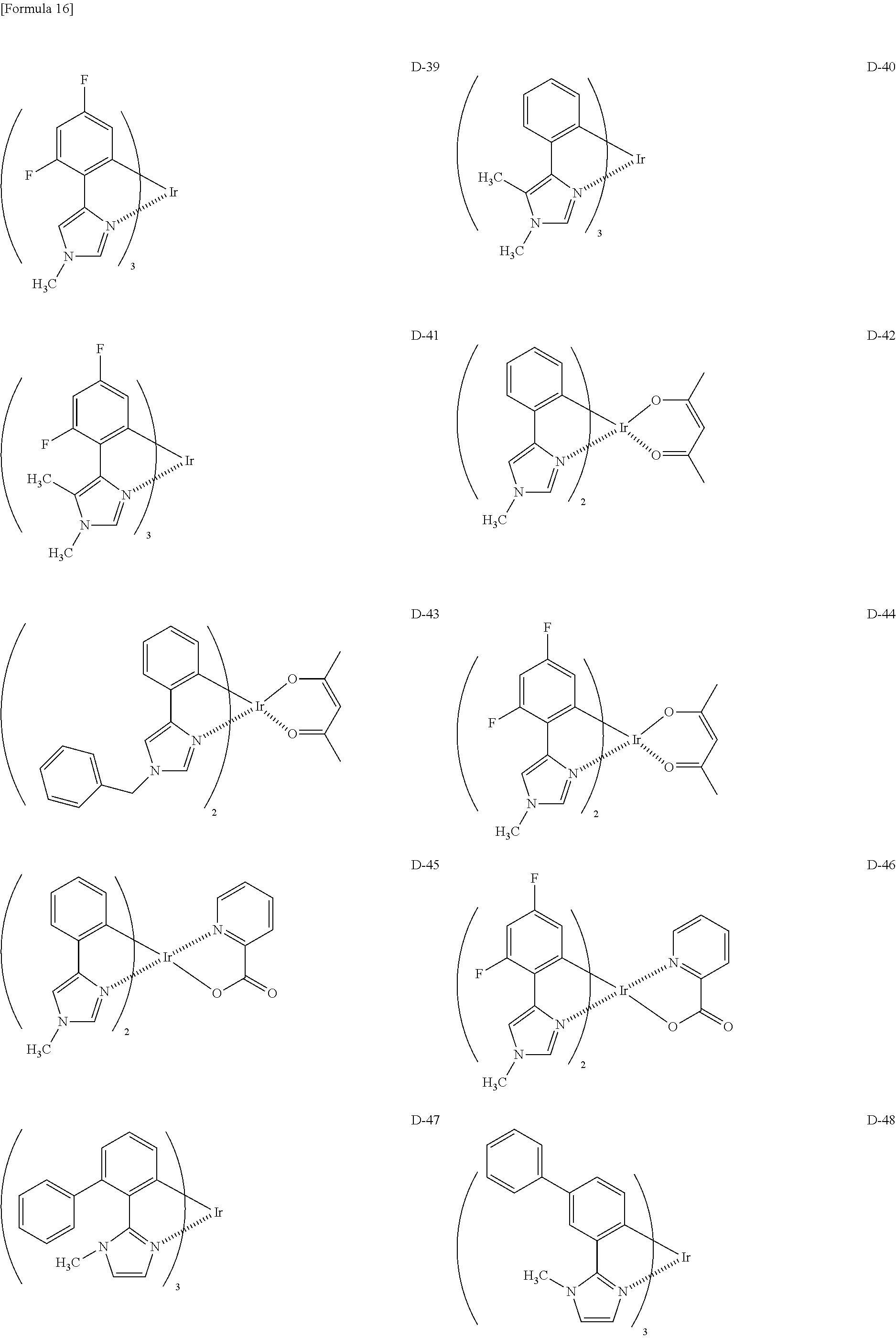

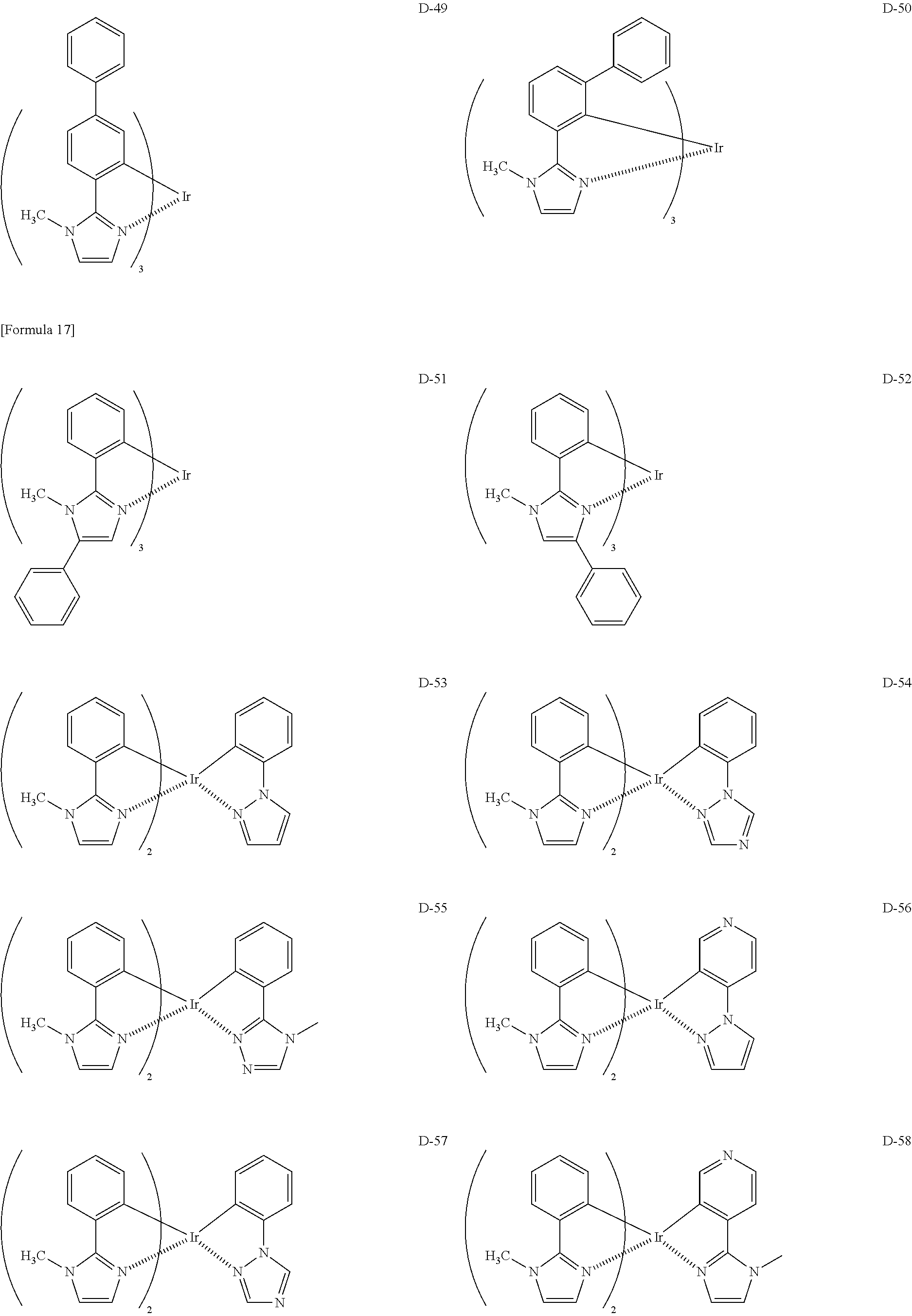

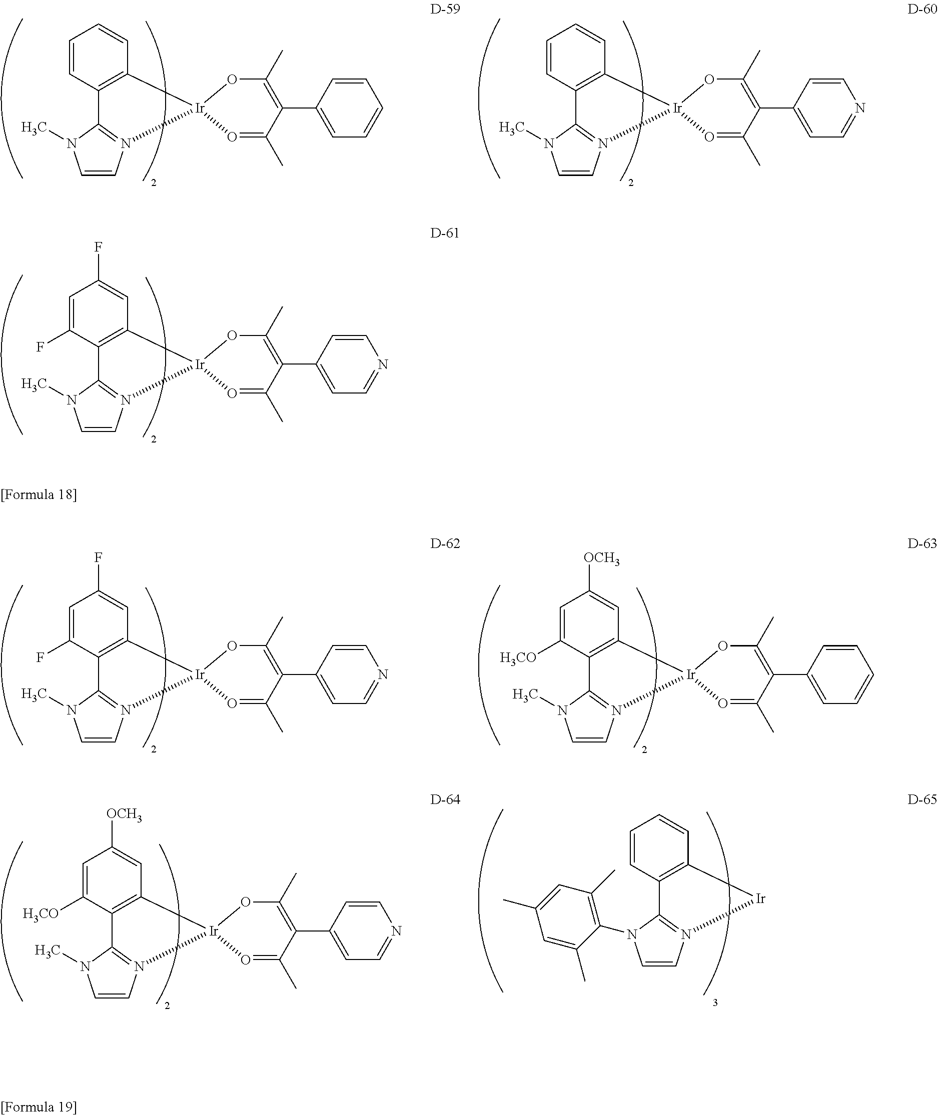

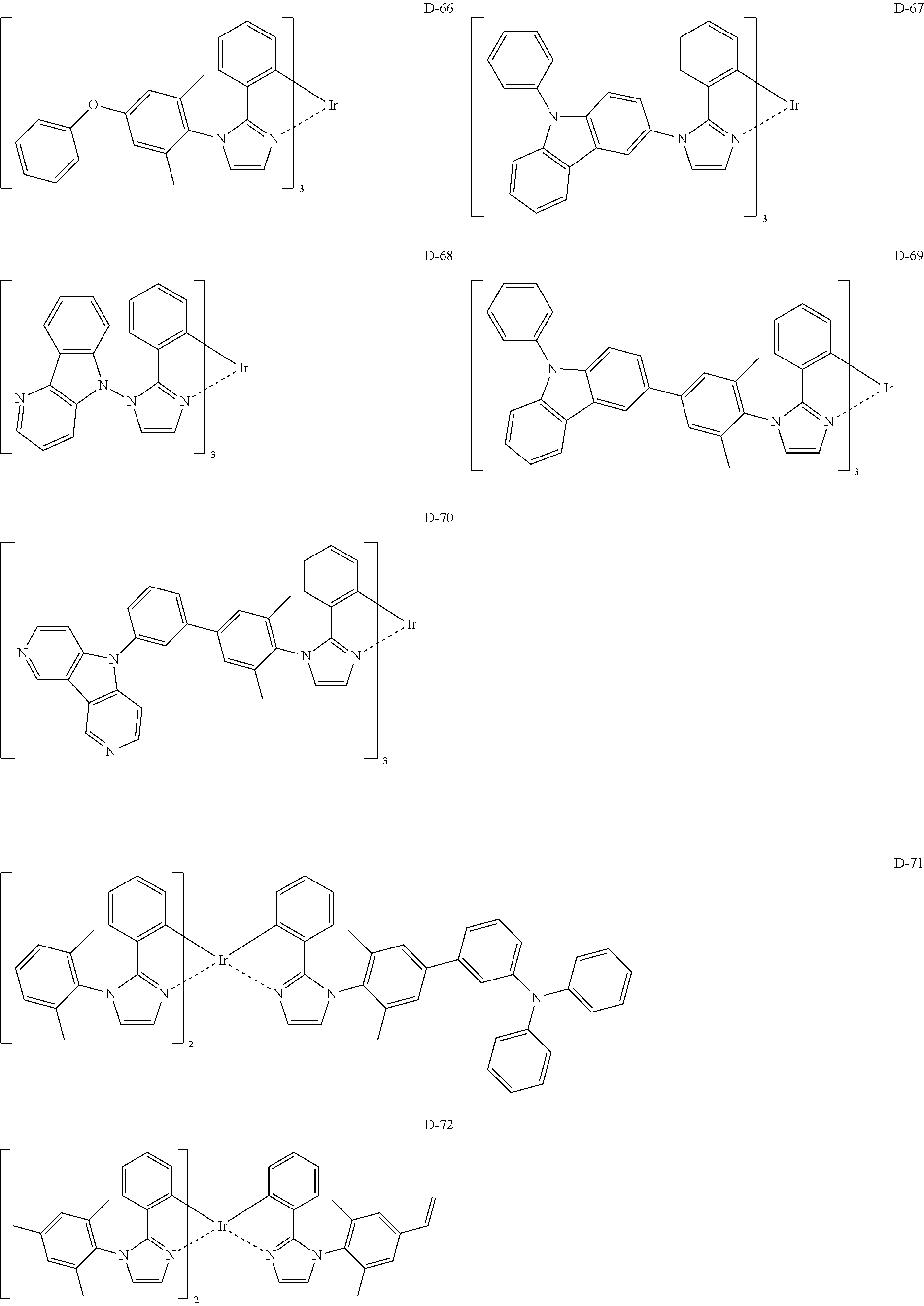

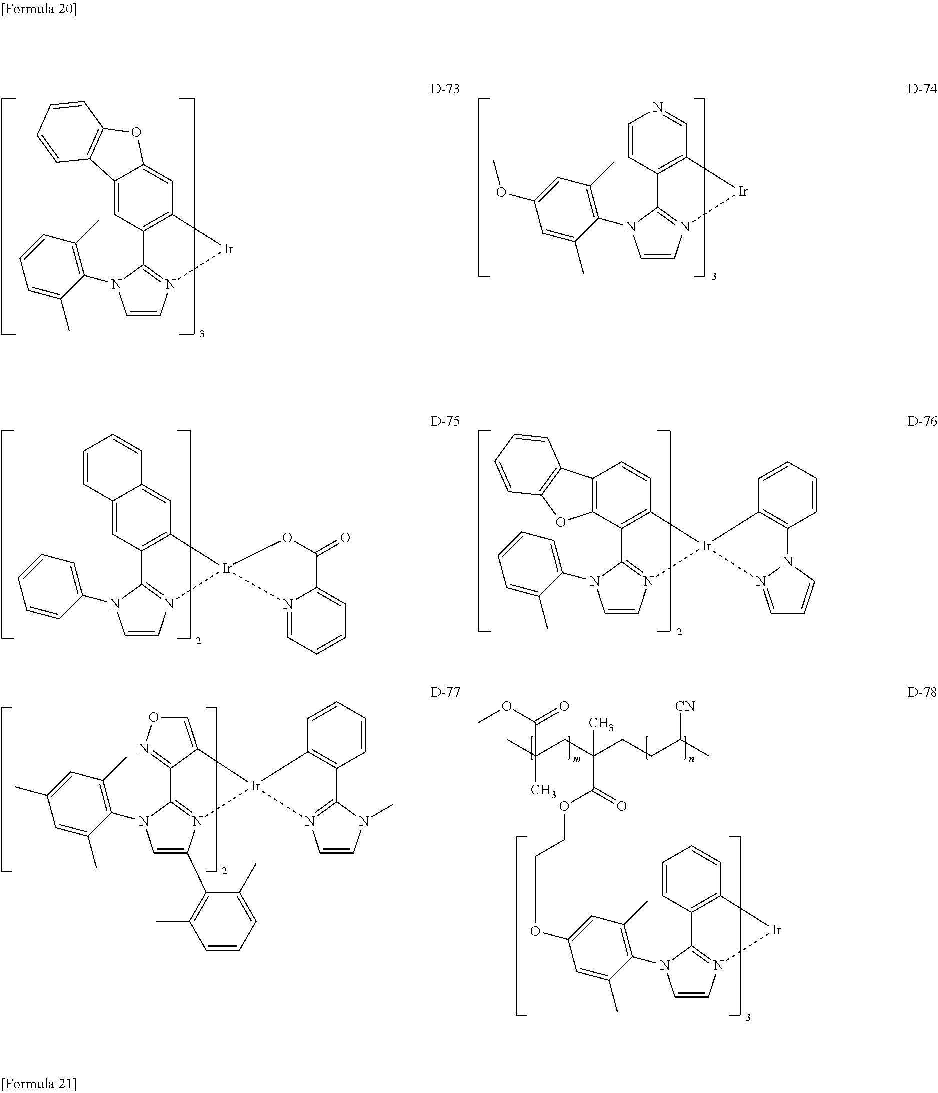

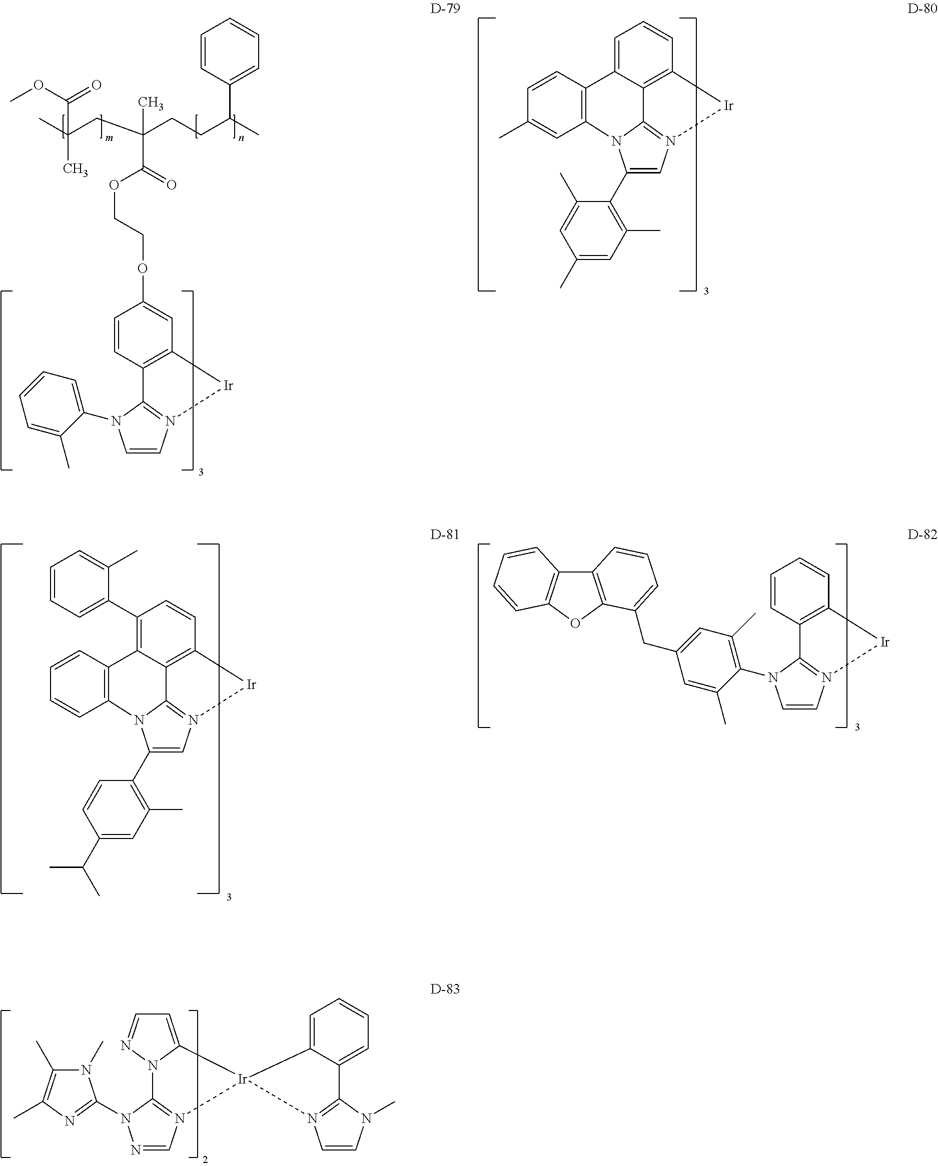

### (3) Fluorescence-Emitting Dopant

Examples of the fluorescence-emitting dopant (also referred to as fluorescent dopant or fluorescence-emitting material) include coumarin dyes, pyran dyes, cyanine dyes, chroconium dyes, squarylium dyes, oxobenzanthracene dyes, fluorescein dyes, rhodamine dyes, pyrylium dyes, perylene dyes, stilbene dyes, polythiophene dyes, and fluorescent rare earth complexes.

### <<Injection Layers: Hole Injection Layer and Electron Injection Layer>>

The organic EL element of the present invention may optionally be provided with one or more injection layers. The injection layers are optionally disposed between the anode and the luminous layer or the anode and the hole transport layer, or between the cathode and the luminous layer or the cathode and the electron transport layer.

The injection layer is provided between the electrode and the organic layer in order to reduce the driving voltage and to improve the luminance, and is described in detail in, for example, “Denkyoku zairyo (Electrode material)”, Div. 2, Chapter 2 (pp. 123-166) of “Yuki EL soshi to sono kogyoka saizensen (Organic EL element and its frontier of industrialization)” (published by NTS Corporation, Nov. 30, 1998). The injection layers are categorized as a hole injection layer (anode buffer layer) and an electron injection layer (cathode buffer layer).

The hole injection layer (anode buffer layer) is described in detail in, for example, Japanese Laid-Open Patent Application Publication Nos. H09-45479, H09-260062, and H08-288069. Specific examples of the hole injection layer include phthalocyanine buffer layers, such as copper phthalocyanine buffer layers, oxide buffer layers, such as vanadium oxide buffer layers, amorphous carbon buffer layers, and polymer buffer layers composed of an electroconductive polymer, such as polyaniline (emeraldine) and polythiophene. Preferred materials of the hole injection layer are also described in Japanese Publication of International Patent Application No. 2003-519432.

The hole injection layer of the present invention may be composed of a plurality of materials, but is preferably composed of a deposited film of a single organic compound. It is because, for example, use of a plurality of materials in combination involves a high risk of a variation in performance due to a variable mixing ratio in the deposited layer, due to variations in concentration of the materials on the surface of a substrate where the layer is deposited.

The hole injection layer may have any thickness, usually within the range of 0.1 to 100 nm, preferably within the range of 1 to 30 nm.

Examples of materials suitable for the electron injection layer disposed between the electron transport layer and the cathode include alkali metal and alkaline earth metal compounds that have a work function of 3 eV or lower. Specific examples of alkali metal compounds include potassium fluoride, lithium fluoride, sodium fluoride, cesium fluoride, lithium oxide, lithium quinoline complexes, and cesium carbonate, among which preferred are lithium fluoride and cesium fluoride.

The electron injection layer may have any thickness, usually within the range of 0.1 to 10 nm, preferably within the range of 0.1 to 2 nm.

### <Blocking Layers: Hole Blocking Layer and Electron Blocking Layer>

The organic EL element of the present invention may optionally be provided with one or more blocking layers. The blocking layer is, for example, a hole blocking layer described in detail in Japanese Laid-Open Patent Application Publication Nos. H11-204258 and H11-204359, and “Yuki EL soshi to sono kogyoka saizensen (Organic EL element and its frontier of industrialization)” (published by NTS Corporation, Nov. 30, 1998, page 237).

The hole blocking layer functions as an electron transport layer in a broad sense, and is composed of a hole blocking material which has electron transportability and has a very low hole transportability. The hole blocking layer transports electrons and blocks holes, resulting in an increased probability of recombination between the electrons and the holes. The electron transport layer with the structure described below may also be used as a hole blocking layer.

The hole blocking layer is preferably disposed adjacent to the luminous layer.

The electron blocking layer functions as a hole transport layer in a broad sense, and is composed of an electron blocking material which has hole transportability and has a very low electron transportability. The electron blocking layer transports holes and blocks electrons, resulting in an increased probability of recombination between the electrons and the holes. The hole transport layer with the structure described below may also be used as an electron blocking layer.

The hole blocking layer and the electron transport layer preferably have a thickness within the range of 3 to 100 nm, more preferably within the range of 5 to 30 nm.

### <Hole Transport Layer>

The hole transport layer is composed of a hole transport material that has hole transportability. The hole injection layer and the electron blocking layer are also categorized into the hole transport layer in a broad sense.

The hole transport layer may have a monolayer or multilayer structure.

The hole transport materials have hole injecting or transporting ability or electron blocking ability, and may be either organic or inorganic materials. Examples of such materials include triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styryl anthracene derivatives, fluorenone derivatives, hydrazone derivatives, stilbene derivatives, silazane derivatives, aniline copolymers, and electroconductive high-molecular weight oligomers, particularly thiophene oligomers.

These materials can be used as hole transport materials, and further examples of preferred materials include porphyrin compounds, aromatic tertiary amine compounds, and styrylamine compounds, among which particularly preferred are aromatic tertiary amine compounds.

Typical examples of the aromatic tertiary amine compounds and the styrylamine compounds include N,N,N′,N′-tetraphenyl-4,4′-diaminophenyl, N,N′-diphenyl-N,N′-bis(3-methylphenyl)-(1,1′-biphenyl)-4,4′-diamine (hereinafter referred to as “TPD”), 2,2-bis(4-di-p-tolylaminophenyl)propane, 1,1-bis(4-di-p-tolylaminophenyl)cyclohexane, N,N,N′,N′-tetra-p-tolyl-4,4′-diaminobiphenyl, 1,1-bis(4-di-p-tolylaminophenyl)-4-phenylcyclohexane, bis(4-dimethylamino-2-methylphenyl)phenylmethane, bis(4-di-p-tolylaminophenyl)phenylmethane, N,N′-diphenyl-N,N′-di(4-methoxyphenyl)-4,4′-diaminobiphenyl, N,N,N′,N′-tetraphenyl-4,4′-diaminodiphenyl ether, 4,4′-bis(diphenylamino)quardriphenyl, N,N,N-tri(p-tolyl)amine, 4-(di-p-tolylamino)-4′-[4-(di-p-tolylamino)styryl]stilbene, 4-N,N-diphenylamino-(2-diphenylvinyl)benzene, 3-methoxy-4′-N,N-diphenylaminostylbenzene, N-phenylcarbazole, compounds having two fused aromatic rings per molecule, described in U.S. Pat. No. 5,061,569, such as 4,4′-bis[N-(1-naphthyl)-N-phenylamino]biphenyl (hereinafter referred to as “NPD”), and compounds described in Japanese Laid-Open Patent Application Publication No. H04-308688, such as 4,4′,4″-tris[N-(3-methylphenyl)-N-phenylamino]triphenylamine (hereinafter referred to as “MTDATA”) in which three triphenylamine units are bonded into a starburst form.

Polymer materials containing the above compounds introduced into their chains or containing the above compounds as main chains can also be used. Inorganic compounds such as p-type Si and p-type SiC can also be used as a hole injection material or a hole transport material.

The hole transport layer may also be composed of any material having so called p-type conductivity. Such materials are described in Japanese Laid-Open Patent Application Publication Nos. H04-297076, 2000-196140, and 2001-102175, J. Appl. Phys., 95, 5773 (2004), Japanese Laid-Open Patent Application Publication No. H11-251067, J. Huang, et al., “Applied Physics Letters”, 80 (2002), p. 139, and Japanese Publication of International Patent Application No. 2003-519432. In the present invention, such materials are preferred, which provide a light-emitting device with higher luminous efficiency.

The hole transport layer may have a monolayer structure composed of one or more of the materials mentioned above.

The hole transport layer may have any thickness, normally within the range of 5 nm to 5 μm, preferably within the range of 5 to 200 nm.

### <Electron Transport Layer>

The electron transport layer is composed of a material having electron transportability.

The electron transport layer may have a monolayer or multilayer structure.

The electron transport material used for the electron transport layer may be selected from any conventionally-known compounds that can transport electrons injected from a cathode to a luminous layer. Examples of such compounds include derivatives of nitro-substituted fluorene, diphenylquinone, thiopyrandioxide, bipyridyl, fluorenylidenemethane, carbodiimide, anthraquinodimethane, anthrone, and oxadiazole. Further examples of the electron transport material include thiadiazole (i.e., a ring in which an oxygen atom in the oxadiazole ring of the oxadiazole derivatives is replaced with a sulfur atom) derivatives, and quinoxaline derivatives having a quinoxaline ring known as an electron-withdrawing group. Polymer materials containing the above compounds introduced into their chains or containing the above compounds as main chains can also be used.

Further examples of the electron transport material include metal complexes of 8-quinolinol, such as tris(8-quinolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, and bis(8-quinolinol)zinc (Znq), and metal complexes formed by replacing the central metal of the above metal complexes with In, Mg, Cu, Ca, Sn, Ga or Pb. Further preferred examples of the electron transport material include a metal-free or metal-containing phthalocyanine and derivatives thereof having an alkyl or sulfonate substituted end. Distyrylpyrazine derivatives known as a material for a luminous layer may also be used as the electron transport material. Inorganic semiconductors such as n-type Si and n-type SiC may also be used as the electron transport material, as well as inorganic semiconductors such as p-type Si and p-type Sic may be used as a hole transport material or a hole injection material for the hole transport layer or the hole injection layer.

The electron transport layer may be composed of a plurality of materials, and may be doped with an alkali metal, an alkaline earth metal, an alkali metal compound, or an alkaline earth metal compound. However, the electron transport layer of the present invention is preferably composed of a deposited film of a single organic compound.

It is because, for example, use of a plurality of materials in combination involves a high risk of a variation in performance due to a variable mixing ratio in the deposited layer, due to variations in concentration of the materials on the surface of a substrate where the layer is deposited.

The organic compound contained in the electron transport layer preferably has a glass transition temperature of 110° C. or higher, which allows high stability under high-temperature preservation and process.

The electron transport layer may have any thickness, normally within the range of 5 nm to 5 μm, preferably within the range of 5 to 200 nm.

### <Support Substrate>

The support substrate (hereinafter, also referred to as substrate, base, or support) 31 of the organic EL element 3 of the present invention may be any type of substrate, for example, glass or plastic substrate. Because light is extracted from the support substrate 31 of the organic EL element 3 of the present invention, the support substrate 31 is transparent. Examples of the preferred transparent support substrate include glass, quartz, and transparent resin films. Particularly, the support substrate is preferably a resin film which can provide a flexible organic EL element.

Examples of the resin film include polyesters, such as poly(ethylene terephthalate) (PET) and poly(ethylene naphthalate) (PEN); polyethylene; polypropylene; cellophane; cellulose esters and derivatives thereof, such as cellulose diacetate, cellulose triacetate (TAC), cellulose acetate butyrate, cellulose acetate propionate (CAP), cellulose acetate phthalate, and cellulose nitrate; poly(vinylidene chloride); poly(vinyl alcohol); poly(ethylene-vinyl alcohol); syndiotactic polystyrene; polycarbonates; norbornene resins; polymethylpentene; polyether ketone; polyimides; polyethersulfones (PESs); polyphenylene sulfide; polysulfones; polyether imides; polyether ketone imides; polyamides; fluororesins; nylons; poly(methyl methacrylate); acrylics or polyarylates; and cycloolefin resins, such as ARTON (product name; manufactured by JSR Corporation) and APEL (product name; manufactured by Mitsui Chemicals, Inc.).

The surface of the resin film may be covered with a coating layer of an inorganic or organic material or a hybrid film of inorganic and organic materials. The resin film is preferably a gas barrier film having water vapor permeability (measured in accordance with JIS K 7129-1992) of 0.01 g/(m²·24 h) or lower, and is preferably a high barrier film having oxygen permeability (measured in accordance with JIS K 7126-1992) of 1×10⁻³ ml/(m²·24 h·atm) or lower and water vapor permeability of 1×10⁻³ g/(m²·24 h) or lower. The resin film more preferably has oxygen permeability of 1×10⁻⁵ ml/(m²·24 h·atm) or lower and water vapor permeability of 1×10⁻⁵ g/(m²·24 h).

The gas barrier layer may be composed of any material that can block infiltration of substances, such as moisture and oxygen, which causes deterioration of the organic EL element. For example, silicon oxide, silicon dioxide and silicon nitride can be used. In order to solve the brittleness of the gas barrier layer, the gas barrier layer preferably has a laminated structure composed of an inorganic layer and an organic material layer. The inorganic layer and organic material layer may be deposited in any order, but are preferably deposited alternately a plurality of times.

The gas barrier layer may be formed by any method, for example, vacuum vapor deposition, sputtering, reactive sputtering, molecular beam epitaxy, cluster ion beam deposition, ion plating, plasma polymerization, atmospheric pressure plasma polymerization, plasma chemical vapor deposition (CVD), laser CVD, thermal CVD, and coating. In particular, the gas barrier layer is preferably produced by an atmospheric pressure plasma polymerization process as described in Japanese Laid-Open Patent Application Publication No. 2004-68143.

### <Sealing>

Examples of a sealing means applicable to the organic EL dev element ice 3 of the present invention include adhesion of a sealing material and a support substrate 31 with an adhesive.

The sealing material may be disposed to cover a display area of the organic EL element. The sealing material may have a concave or flat shape.

Transparency and electric insulation of the sealing material are not specifically limited.

Specific examples of the sealing material include glass plates, composite materials of a polymer plate and film, and composite materials of a metal plate and film. Specific examples of materials for the glass plate include soda-lime glass, barium-strontium-containing glass, lead glass, aluminosilicate glass, borosilicate glass, barium borosilicate glass, and quartz. Examples of materials for the polymer plate include polycarbonates, acrylics, poly(ethylene terephthalate), polyether sulfides, and polysulfones. Examples of materials for the metal plate include one or more metals or alloys selected from the group consisting of stainless steel, iron, copper, aluminum, magnesium, nickel, zinc, chromium, titanium, molybdenum, silicone, germanium, and tantalum.

In the present invention, a polymer film and a metal film may be preferably used as a sealing material, because they contribute to production of low-profile organic EL elements. The polymer film preferably has an oxygen permeability of 1×10⁻³ ml/(m²·24 h·atm) or lower and a water vapor permeability of 1×10⁻³ g/(m²·24 h) or lower, more preferably an oxygen permeability of 1×10⁻⁵ ml/(m²·24 h·atm) or lower and a water vapor permeability of 1×10⁻⁵ g/(m²·24 h).

The sealing material may be processed into a concave shape through any process, for example, sandblasting or chemical etching.

Specific examples of the adhesive for sealing include light-curable or thermosetting adhesives having reactive vinyl groups, such as acrylic acid oligomers and methacrylic acid oligomers; moisture-curable resins, such as 2-cyanoacrylic acid esters; thermosetting and chemically curable adhesives (two-component adhesives), such as epoxy adhesives; hot-melt adhesives, such as polyamide adhesives, polyester adhesives, and polyolefin adhesives; and cation-curable and ultraviolet-curable epoxy resin adhesives.

The adhesive for sealing can preferably cure and adhere at a temperature within the range from room temperature (25° C.) to 80° C. to prevent deterioration of the organic EL element during a thermal treatment. The adhesive may also contain a desiccant dispersed therein. The adhesive may be coated on a target portion with a commercially available dispenser or by a screen printing process.

The gap between the sealing material and the display area of the organic EL element is preferably filled with an inactive gas, such as nitrogen gas and argon gas, or an inactive liquid, such as fluorohydrocarbon and silicon oil, for the purpose of forming a gaseous or a liquid phase. The gap may also be a vacuum or filled with a moisture-absorbing compound.

Examples of the moisture-absorbing compound include metal oxides, such as sodium oxide, potassium oxide, calcium oxide, barium oxide, magnesium oxide, and aluminum oxide; sulfates, such as sodium sulfate, calcium sulfate, magnesium sulfate, and cobalt sulfate; metal halides, such as calcium chloride, magnesium chloride, cesium fluoride, tantalum fluoride, cerium bromide, magnesium bromide, barium iodide, and magnesium iodide; and perchlorates, such as barium perchlorate and magnesium perchlorate. Anhydrous salt are preferably used for sulfates, metal halides, and perchlorates.

### <Protective Film and Protective Plate>

In order to enhance the mechanical strength of the organic EL element, a protective film or plate may be provided on the outer side of the sealing film. If the sealing is performed by the sealing film described above, the mechanical strength of the organic EL element is not necessarily high, and thus such a protective film or plate is preferably formed. Examples of a material usable for such a protective film or plate include the same glass plates, composite materials of a polymer plate and film, and composite materials of a metal plate and film as those which can be used for the sealing. A polymer film is preferably used, from the perspective of weight saving and thinning of the organic EL element.

### <Anode>

The anode 32 of the organic EL element of the present invention is preferably composed of an electrode material such as a metal, an alloy, an electrically conductive compound, or a mixture thereof that has a high work function (4 eV or higher). Specific examples of such an electrode material include conductive transparent materials such as metals such as Au, Ag, and Al, CuI, indium-tin oxide (hereinafter, abbreviated as “ITO”), SnO₂, and ZnO. Amorphous materials applicable to production of a transparent conductive film, such as IDIXO (In₂O₃-ZnO), may also be used.

The anode 32 may also be produced by forming the electrode material into a thin film by a method such as vapor deposition or sputtering, and then producing a desired shape of pattern by a method such as a photolithographic process. If high pattern accuracy (approximately 100 μm or higher) is not required, the pattern may be formed via a mask having a desired shape during the time of vapor deposition or sputtering of the electrode material. Alternatively, the film may be formed with a material which can be coated, such as an organic conductive compound, through a wet process, for example, printing or coating.

Because luminescence is extracted from the anode 32 in the present invention, the anode 32 preferably has a transmittance of above 10%.

The sheet resistance of the anode 32 is preferably several hundred ohms per sheet or lower.

The thickness of the anode 32 is normally within the range of 5 to 1000 nm, preferably within the range of 5 to 200 nm, although it depends on the electrode material.

### <Cathode>

The cathode 34 is preferably composed of an electrode material such as a metal, an alloy, an electrically conductive compound, or a mixture thereof. Specific examples of such an electrode material include sodium, sodium-potassium alloys, magnesium, lithium, magnesium/copper mixtures, magnesium/silver mixtures, magnesium/aluminum mixtures, magnesium/indium mixtures, aluminum/aluminum oxide (Al₂O₃) mixtures, indium, lithium/aluminum mixtures, rare earth metals, silver, and aluminum. From the perspective of electron injection and resistance to oxidation, it is preferable to use a mixture of an electron-injecting metal and a second metal which is a stable metal with a higher work function than the electron-injecting metal, among these materials. Preferred examples of such a mixture include magnesium/silver mixtures, magnesium/aluminum mixtures, magnesium/indium mixtures, aluminum/aluminum oxide (Al₂O₃) mixtures, lithium/aluminum mixtures, aluminum, and silver.

The cathode 34 can be produced by forming such an electrode material into a thin film using any process, for example, vapor deposition or sputtering.

The sheet resistance of the cathode 34 is preferably several hundred ohms per sheet or lower. The film thickness of the cathode 34 is normally within the range of 5 nm to 5 μm, preferably within the range of 5 to 200 nm.

Because light is extracted from the side of the support substrate 31 in the organic EL element 3 according to the present invention, the anode 32 is transparent and the cathode 34 is opaque in the example of the figure. When the cathode 34 is disposed on the side of the support substrate 31, a transparent cathode 34 and an opaque anode 32 constitute the organic EL element 3.

### <<Patterning Method of Organic EL Element>>

The organic functional layer 33 in the organic EL element 3 according to the present invention has a predetermined region patterned by light irradiation, which changes the function and the luminance of the predetermined region.

The patterning method of the organic EL element 3 is divided into a laminating process to manufacture the organic EL element 3 and a light irradiation process to irradiate light to the manufactured organic EL element 3.

### (1) Laminating Process

The organic EL element 3 is manufactured first. Specifically, a laminating process to laminate an anode 32, an organic functional layer 33, and a cathode 34 on a support substrate 31 is conducted.

First, a support substrate 31 is prepared. An appropriate material for electrodes (e.g. anode 32) is formed into a thin film having a thickness of 1 μm or less, preferably in the range of 10 to 200 nm on the support substrate 31 by vapor deposition, sputtering, or any other process. At the same time, extracting electrode (not shown in the drawings) for connection to an external power source may be formed at the edge of the anode 32 by vapor deposition or any other appropriate process.

A organic functional layer 33 including a hole injection layer, a hole transport layer, a luminous layer, and an electron transport layer are laminated on the anode.

These layers are formed by, for example, spin coating, casting, an inkjet technique, vapor deposition, or printing, most preferably vacuum deposition or spin coating that readily provides homogeneous layers and minimizes the formation of pin holes. Each layer may be formed by a different technique. Preferred conditions for the vapor deposition, which depend on the compound used, are a boat temperature in the range of 50 to 450° C., a vacuum in the range of (1×10⁻⁶) to (1×10⁻²) Pa, a deposition rate in the range of 0.01 to 50 nm/s, a substrate temperature in the range of −50 to 300° C., and a film thickness in the rage of 0.1 to 5 μm.

As described above, the organic functional layer 33 is formed. The cathode 34 is then formed on the organic functional layer 33 by, for example, vapor deposition, sputtering, or any other appropriate technique. At this time, the cathode 34 is insulated from the anode 32 by the organic functional layer 33 and is patterned such that the terminal of the cathode 34 is extracted from above the organic functional layer 33 and resides on the periphery of the support substrate 31.

After the formation of the cathode 34, the support substrate 31, the anode 32, the organic functional layer 33, and the cathode 34 are sealed with a sealing material. Specifically, the sealing material is applied to the support substrate 31 so as to cover at least the organic functional layer 33, while the terminals of the anode 32 and cathode 34 are exposed.

### (2) Light Irradiation Process

By conducting a light irradiation process irradiating light to the predetermined region of the organic EL element 3 manufactured as described above, the luminance function of the predetermined region in the organic functional layer 33 changes. An organic EL element 3 which emits light in a predetermined pattern of shape is thus manufactured.

“A change in the luminance function by light irradiation” is used to mean a change in luminance of the organic functional layer caused by the change in the function of a hole-transporting material and the like which constitute the organic functional layer by light irradiation.

In the light irradiation process, any method of irradiating light may be used as long as a predetermined light is irradiated to the predetermined region of the organic functional layer 33 and changes the luminance of the irradiated region. The method is not limited specifically but exemplified by patterning with mask, point drawing or line drawing with laser, and the like.

Any light may be irradiated in the light irradiation process as long as it can change the luminance of the organic functional layer 33 of the manufactured organic EL element 3. In terms of efficient change in luminance of the organic functional layer 33, an ultraviolet ray is preferably included.

In the present invention, an ultraviolet ray is defined as an electromagnetic wave having a wavelength longer than that of an X ray and shorter than the minimum wavelength of visible light, specifically in the range of 1 to 400 nm.

The generating means and irradiating means of an ultraviolet ray are not particularly limited, an ultraviolet ray is generated and irradiated by a conventionally-known devices. Specific examples of a light source include a high pressure mercury lamp, a low pressure mercury lamp, hydrogen (deuterium) lamp, rare gas (xenon, argon, helium, neon, etc.) discharge lamp, nitrogen laser, excimer laser (XeCl, XeF, KrF, KrCl, etc.), and hydrogen laser. A harmonic light (THG (Third Harmonic Generation) light of YAG laser etc.) of a visible (LD) laser to an infrared laser may also be used.

The irradiation process is preferably conducted after sealing the organic EL device 3 for simplicity, but may be conducted in manufacturing the organic EL element 3, specifically during the above-described lamination process. In this case, the light irradiation described above is preferably conducted to the hole injection layer or the hole transport layer, immediately after forming the layer. This improves an accuracy of patterning, because light irradiation can change the luminance without through other constituent layers or a sealing material.

In the irradiation process, the amount of light irradiation can be changed by controlling the strength or time of light irradiation to the organic functional layer 33 and thereby the luminance of the region irradiated with light can be changed according to the amount of the light irradiation. The increase of light irradiation results in reduction in luminance; the decrease of light irradiation results in less reduction in luminance. Accordingly, when the light irradiation is zero, that is, when the light is not irradiated, the luminance becomes the maximum.

Thus, an organic EL element 3 which emits light with a desired pattern of shape can be manufactured. In manufacturing the organic EL element 3, the organic functional layer 33 to the cathode 34 are preferably formed consistently in a single vacuuming processes. The support substrate 31 may be taken out from the vacuum atmosphere to conduct a different formation method, which requires a care to carry out the process in a dry inert gas atmosphere.

When a DC voltage is applied to the organic EL element 3 manufactured as above, light emission can be observed by applying a voltage of about 2 to 40V to the electrodes arranged on the both sides of the organic functional layer 33 to emit light. An AC voltage of any waveform may be applied.

In this case, a current flows only at the patterned region. Accordingly, energy consumption can be reduced compared to LED that conducts light even to the unnecessary regions.

### EXAMPLES

The present invention is further described below in detail with reference to the following examples, but the present invention is not limited by these examples. “%” used in the examples mean “mass %” unless otherwise noted.

<<Preparation of Organic EL Element s>>

An anode of indium tin oxide (ITO) with a thickness of 150 nm was formed on a support substrate of a glass substrate having a size of 30 mm by 60 mm and a thickness of 0.7 mm, and was patterned. After the patterning, the transparent support substrate provided with the ITO transparent electrode was cleaned with isopropyl alcohol by ultrasonic agitation, was dried in a dry nitrogen gas atmosphere, and was cleaned in a UV ozone environment for 5 minutes. The transparent support substrate was fixed to a substrate holder in a commercially available vacuum evaporation system.

Materials of optimum amounts for individual layers were placed into individual vapor deposition crucibles in the vacuum evaporation system. The vapor deposition crucibles used were composed of a material for resistance heating, such as molybdenum or tungsten.

After the apparatus was evacuated to a degree of vacuum of 1×10⁻⁴ Pa, the vapor deposition crucible containing Compound M-4 was electrically heated to deposit Compound M-4 onto the transparent support substrate at a deposition rate of 0.1 nm/sec, thereby forming a hole injection layer with a thickness of 15 nm.

Compound M-2 was then deposited in the same way into a hole transport layer with a thickness of 40 nm.

Compounds BD-1, GD-1, RD-1, H-1, and H-2 were then codeposited at a deposition rate of 0.1 nm/sec such that the deposited layer contained 5% compound BD-1, 17% GD-1, 0.8% RD-1, thereby forming a first white luminous layer with a thickness of 30 nm.

Subsequently, Compound E-1 was deposited at a deposition rate of 0.1 nm/sec, thereby forming an electron transport layer with a thickness of 30 nm.

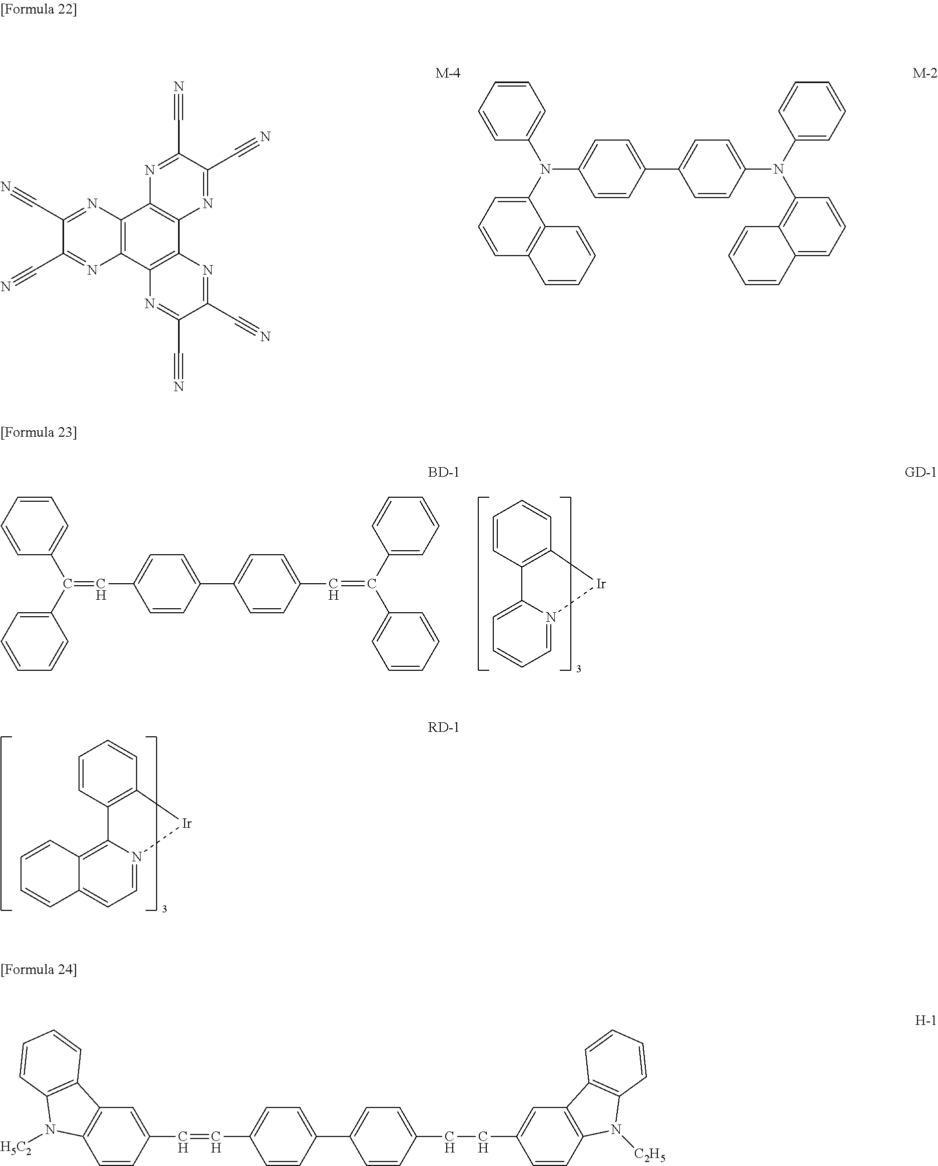

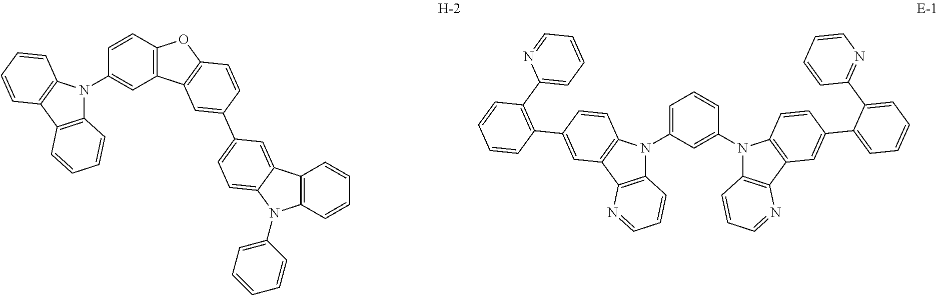 [SMILES: c1ccc(-n2c3ccccc3c3cc(-c4ccc5oc6ccc(-n7c8ccccc8c8ccccc87)cc6c5c4)ccc32)cc1 ; c1ccc(-c2ccccc2-c2ccc3c(c2)c2ncccc2n3-c2cccc(-n3c4ccc(-c5ccccc5-c5ccccn5)cc4c4ncccc43)c2)nc1]

LiF was deposited into a thickness of 1.5 nm, thereby forming an electron injection layer. Subsequently, aluminum was deposited into a thickness of 110 nm, thereby forming a cathode.

The non-luminous surface of the above element was then covered with a glass case, thereby preparing the organic EL element.

The vapor deposition surface of the organic EL element prepared above is covered with a glass case. Sealing was performed under a high-purity (99.999% or higher) nitrogen gas atmosphere in a glovebox to avoid exposure of the organic EL element to the air.

Under pressure reduction, a pattern mask is adhered to the surface of the support substrate opposite to the surface on which above-described layers are formed. An ultraviolet ray for patterning is irradiated from the side of the support substrate for 3 hours using a UV tester (SUV-W151: 100 mW/cm², manufactured by Iwasaki Electric Co. Ltd).

### <<Preparation of Surface Emitting Device>>

A soda glass (a blue sheet glass) formed in a plate shape and strengthened by chemical etching at the end is used as a fixed substrate. The fixed substrate is fixed horizontally. A transparent double-sided adhesive sheet (LUCIACS series manufactured by Nitto Denko Corporation) is adhered to the fixed substrate by a roll laminate method, and a circularly polarizing plate is stuck to the fixed substrate via the transparent double-sided adhesive sheet. Further, the surface of the circularly polarizing plate opposite to the fixed substrate is adhered to the same transparent double-sided adhesive sheet as above by a roll laminate method, and is stuck to the side of the support substrate of the above-prepared organic EL element via the transparent double-sided adhesive sheet. The surface emitting device according to the present invention is thus prepared.

### <<Evaluation of Surface Emitting Device>>

As a result of driving the above-prepared surface emitting device, it could be confirmed that the formed pattern could be observed when the light was emitted, and the light emission surface appeared as black and the patterned region could not be visually recognized when the light was not emitted

### INDUSTRIAL APPLICABILITY

As described above, the present invention is suitable for providing a surface emitting device whose light emission surface appears as black when the light is not emitted and whose patterned region cannot be visually recognized when the light is not emitted, and a smart device provided with the same.

### REFERENCE NUMERAL LIST

1 fixed substrate
2 circularly polarizing plate
3 organic EL element
10 surface emitting device
20 liquid crystal display
31 support substrate
32 anode
33 organic functional layer
34 cathode
100 smart device

1. A surface emitting device comprising;
an organic electroluminescent element having a pair of electrodes formed on a support substrate and an organic functional layer comprising at least a luminous layer between the pair of electrodes, wherein a predetermined region of the organic functional layer is patterned by light irradiation;
a fixed substrate facing the support substrate and supporting the organic electroluminescent element; and
a circularly polarizing plate between the organic electroluminescent element and the fixed substrate.

2. The surface emitting device of claim 1, wherein a layer patterned by the light irradiation is a hole transport layer or a hole injection layer in the organic functional layer.

3. A smart device provided with the surface emitting device of claim 1.

4. A smart device provided with the surface emitting device of claim 2.
